(19) United States
(12) Patent Application Publication
(10) Pub. No.: US 2026/0094657 A1
(43) Pub. Date: Apr. 2, 2026

(54) METHODS OF OPERATING MEMORY DEVICE AND RELATED APPARATUSES

(71) Applicant: YANGTZE MEMORY TECHNOLOGIES CO., LTD., Wuhan (CN)

(72) Inventor: Teng ZHOU, Wuhan (CN)

(21) Appl. No.: 19/325,317

(22) Filed: Sep. 10, 2025

(30) Foreign Application Priority Data
Sep. 27, 2024 (CN) 2024113703282

(51) Int. Cl. G11C 29/02; G11C 16/34; G11C 29/52

(52) U.S. Cl. CPC G11C 29/022; G11C 16/3404; G11C 29/52

(57) ABSTRACT

A method of operating a memory device includes: reading a first logical page with a first set of read voltage levels to obtain a first read result; reading the first logical page with a second set of read voltage levels having a first offset relative to the first set of read voltage levels to obtain a second read result; reading the first logical page with a third set of read voltage levels having a second offset, different from the first offset, relative to the first set of read voltage levels to obtain a third read result; reading a second logical page different from the first logical page with a fourth set of read voltage levels to obtain a fourth read result; determining a set of optimal read voltage levels for the first logical page based on the first to fourth read results.

### CROSS-REFERENCE TO RELATED APPLICATIONS

The present disclosure claims priority to Chinese Patent Application No. 2024113703282, which was filed Sep. 27, 2024, and is hereby incorporated herein by reference in its entirety.

### TECHNICAL FIELD

The present disclosure relates to the field of semiconductor technology, and more particularly, to a method of operating a memory device, a memory device, a memory controller, and a memory system.

### BACKGROUND

A memory device such as an NAND flash memory is a low-cost, high-density, non-volatile solid-state storage medium that can be electrically erased and re-programmed. The memory device includes an array of memory cells. The memory cell is read by comparing a voltage stored by the memory cell with a read voltage that is used. For example, it can be considered that a memory cell with a voltage lower than the read voltage stores a bit “1”, while a memory cell with a voltage higher than the read voltage stores a bit “0”.

### SUMMARY

A brief overview about the present disclosure is given hereinafter in order to provide a basic understanding about some aspects of the present disclosure. However, it should be understood that this overview is not an exhaustive overview about the present disclosure. It is not intended to determine a key or important part of the present disclosure, nor is it intended to limit the scope of the present disclosure. The purpose thereof is merely to give certain concepts about the present disclosure in a simplified form, as a preface to a more detailed description given later.

According to a first aspect of the present disclosure, a method of operating a memory device is provided.

The method includes performing, with a first set of read voltage levels for respective read voltages corresponding to a first logical page of the memory device, a read operation on the first logical page to obtain a first read result of the first logical page.

The method further includes performing, with a second set of read voltage levels for the respective read voltages corresponding to the first logical page, a read operation on the first logical page to obtain a second read result of the first logical page, wherein the second set of read voltage levels has a first offset relative to the first set of read voltage levels.

The method further includes performing, with a third set of read voltage levels for the respective read voltages corresponding to the first logical page, a read operation on the first logical page to obtain a third read result of the first logical page, wherein the third set of read voltage levels has a second offset relative to the first set of read voltage levels, the second offset being different from the first offset.

The method further includes performing, with a fourth set of read voltage levels for respective read voltages corresponding to a second logical page of the memory device, a read operation on the second logical page to obtain a fourth read result of the second logical page, the second logical page being different from the first logical page.

The method further includes determining a set of optimal read voltage levels for the respective read voltages corresponding to the first logical page based on the first read result, the second read result, the third read result, and the fourth read result.

According to a second aspect of the present disclosure, a memory device is provided. The memory device includes an array of memory cells and a peripheral circuit coupled to the array of memory cells. The peripheral circuit is configured to perform the method in accordance with the first aspect of the present disclosure.

According to a third aspect of the present disclosure, a memory system is provided. The memory system includes a memory controller and a memory device coupled to the memory controller. The memory device includes an array of memory cells and a peripheral circuit, the peripheral circuit being coupled to the array of memory cells and configured to perform the following operations.

The operations include performing, with a first set of read voltage levels for respective read voltages corresponding to a first logical page of the array of memory cells, a read operation on the first logical page to obtain a first read result of the first logical page.

The operations further include performing, with a second set of read voltage levels for the respective read voltages corresponding to the first logical page, a read operation on the first logical page to obtain a second read result of the first logical page, wherein the second set of read voltage levels has a first offset relative to the first set of read voltage levels.

The operations further include performing, with a third set of read voltage levels for the respective read voltages corresponding to the first logical page, a read operation on the first logical page to obtain a third read result of the first logical page, wherein the third set of read voltage levels has a second offset relative to the first set of read voltage levels, the second offset being different from the first offset.

The operations further include performing, with a fourth set of read voltage levels for respective read voltages corresponding to a second logical page of the array of memory cells, a read operation on the second logical page to obtain a fourth read result of the second logical page, the second logical page being different from the first logical page.

The operations further include determining a set of optimal read voltage levels for the respective read voltages corresponding to the first logical page based on the first read result, the second read result, the third read result, and the fourth read result.

According to a fourth aspect of the present disclosure, a memory controller configured to control a memory device is provided. The memory controller includes a memory interface for connecting the memory controller with the memory device, a processor, and a memory coupled to the processor and storing instructions which, when executed by the processor, cause the processor to perform the following operations.

The operations include instructing the memory interface to send a first read command to the memory device to perform a read operation on a first logical page of the memory device with a first set of read voltage levels for respective read voltages corresponding to the first logical page, and receive a first read result of the first logical page from the memory device.

The operations further include instructing the memory interface to send a second read command to the memory device to perform a read operation on the first logical page with a second set of read voltage levels for the respective read voltages corresponding to the first logical page, and receive a second read result of the first logical page from the memory device, wherein the second set of read voltage levels has a first offset relative to the first set of read voltage levels.

The operations further include instructing the memory interface to send a third read command to the memory device to perform a read operation on the first logical page with a third set of read voltage levels for the respective read voltages corresponding to the first logical page, and receive a third read result of the first logical page from the memory device, wherein the third set of read voltage levels has a second offset relative to the first set of read voltage levels, the second offset being different from the first offset.

The operations further include instructing the memory interface to send a fourth read command to the memory device to perform a read operation on a second logical page of the memory device with a fourth set of read voltage levels for respective read voltages corresponding to the second logical page, and receive a fourth read result of the second logical page from the memory device, the second logical page being different from the first logical page.

The operations further include determining a set of optimal read voltage levels for the respective read voltages corresponding to the first logical page based on the first read result, the second read result, the third read result, and the fourth read result.

According to a fifth aspect of the present disclosure, a memory system is provided. The memory system includes a memory device and a memory controller coupled to the memory device and configured to perform the following operations.

The operations include sending a first read command to the memory device to perform a read operation on a first logical page of the memory device with a first set of read voltage levels for respective read voltages corresponding to the first logical page, and receiving a first read result of the first logical page from the memory device.

The operations further include sending a second read command to the memory device to perform a read operation on the first logical page with a second set of read voltage levels for the respective read voltages corresponding to the first logical page, and receiving a second read result of the first logical page from the memory device, wherein the second set of read voltage levels has a first offset relative to the first set of read voltage levels.

The operations further include sending a third read command to the memory device to perform a read operation on the first logical page with a third set of read voltage levels for the respective read voltages corresponding to the first logical page, and receiving a third read result of the first logical page from the memory device, wherein the third set of read voltage levels has a second offset relative to the first set of read voltage levels, the second offset being different from the first offset.

The operations further include sending a fourth read command to the memory device to perform a read operation on a second logical page of the memory device with a fourth set of read voltage levels for respective read voltages corresponding to the second logical page, and receiving a fourth read result of the second logical page from the memory device, the second logical page being different from the first logical page.

The operations further include determining a set of optimal read voltage levels for the respective read voltages corresponding to the first logical page based on the first read result, the second read result, the third read result, and the fourth read result According to a sixth aspect of the present disclosure, an electronic device is provided. The electronic device includes one or more processors and a memory coupled to the one or more processors and storing computer-executable instructions which, when executed by the one or more processors, cause the one or more processors to perform the method in accordance with the first aspect of the present disclosure.

According to a seventh aspect of the present disclosure, a non-transitory storage medium storing computer-executable instructions thereon is provided. The computer-executable instructions, when executed by one or more processors, cause the one or more processors to perform the method in accordance with the first aspect of the present disclosure.

According to an eighth aspect of the present disclosure, a computer program product is provided. The computer program product includes instructions which, when executed by a processor, implement the method in accordance with the first aspect of the present disclosure.

### BRIEF DESCRIPTION OF THE DRAWINGS

From the following description of implementations of the present disclosure shown in conjunction with the drawings, the foregoing and other features and advantages of the present disclosure will become clear. The drawings are incorporated herein and form a part of the specification, which are further used to explain the principles of the present disclosure and enable those skilled in the art to make and use the present disclosure.

FIG. 1 shows a schematic block diagram of an illustrative system according to some implementations of the present disclosure.

FIGS. 2A and 2B (collectively referred to herein as FIG. 2) show schematic diagrams of an illustrative memory card and an illustrative solid-state drive (SSD) according to some implementations of the present disclosure.

FIG. 3 shows a schematic diagram of an illustrative memory device including a peripheral circuit according to some implementations of the present disclosure.

FIG. 4 shows a schematic diagram of a cross-section of an illustrative array of memory cells including memory strings according to some implementations of the present disclosure.

FIG. 5 shows a schematic block diagram of an illustrative memory device including an array of memory cells and peripheral circuits according to some implementations of the present disclosure.

FIG. 6 shows a schematic block diagram of a memory controller according to some implementations of the present disclosure.

FIGS. 7A and 7B (collectively referred to herein as FIG. 7) show distributions of threshold voltages of memory cells of a memory device according to some implementations of the present disclosure.

FIG. 8 shows a flowchart of a method of operating a memory device according to some implementations of the present disclosure.

FIGS. 9A and 9B (collectively referred to herein as FIG. 9) show a flowchart of an illustrative process in which a method of operating a memory device according to an implementation of the present disclosure is applied.

FIGS. 10A, 10B, and 10C (collectively referred to herein as FIG. 10) show a schematic diagram of bit flipping caused by offsetting read voltage levels in the process of FIG. 9.

FIGS. 11A and 11B (collectively referred to herein as FIG. 11) show a flowchart of another illustrative process in which a method of operating a memory device according to an implementation of the present disclosure is applied.

FIGS. 12A, 12B, and 12C (collectively referred to herein as FIG. 12) show a schematic diagram of bit flipping caused by offsetting read voltage levels in the process of FIG. 11.

FIG. 13 shows a schematic block diagram of an electronic device according to some implementations of the present disclosure.

Note that in the implementations illustrated hereinafter, sometimes the same reference numerals are jointly used across different drawings to represent the same parts or parts with the same function, and repeated descriptions thereof are omitted. In some cases, similar numbers and letters are used to represent similar items. Therefore, once an item is defined in a drawing, it does not need to be further discussed in subsequent drawings.

For ease of understanding, positions, dimensions, ranges, and the like of the structures shown in the drawings or the like sometimes do not represent actual positions, dimensions, ranges, and the like. Therefore, the present disclosure is not limited to the positions, dimensions, ranges, and the like disclosed in the drawings or the like.

### DETAILED DESCRIPTION

Various implementations of the present disclosure will be described below in detail with reference to the drawings. It should be noted that: unless otherwise specifically illustrated, numerical expressions, numerical values, and relative arrangements of components and steps set forth in these implementations do not limit the scope of the present disclosure.

In fact, the following description of at least one implementation is merely illustrative, and in no way constitute any limitation on the present disclosure and the application or use thereof. In other words, structures and methods herein are shown in an illustrative manner to illustrate different implementations of the structures and the methods in the present disclosure. However, those skilled in the art will understand that they merely illustrate illustrative manners to implement the present disclosure rather than exhaustive ones. Moreover, the drawings are not necessarily drawn to scale, and some features may be enlarged to show details of specific components.

In addition, technologies, methods, and devices known to a person of ordinary skill in the related art may not be discussed in detail, but in appropriate cases, the technologies, methods, and devices shall be regarded as a part of the specification.

In all examples that are shown and discussed herein, any specific value should be interpreted only as an example but not as a limitation. Therefore, there may be different values for other examples of the implementations.

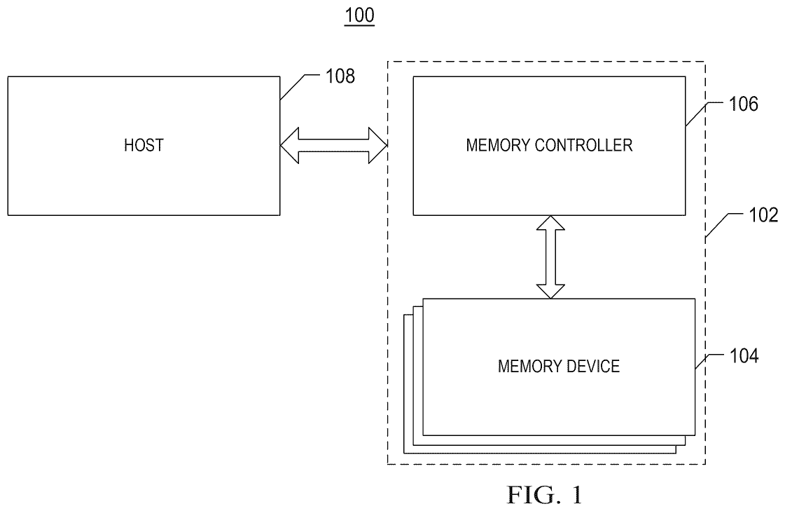

Referring to FIG. 1, FIG. 1 shows a schematic block diagram of an illustrative system 100 according to some implementations of the present disclosure. The system 100 may be a mobile phone, a desktop computer, a laptop computer, a tablet computer, a vehicle computer, a game console, a printer, a positioning device, a wearable electronic device, a smart sensor, a virtual reality device, an augmented reality device, or any other suitable electronic device having a memory device therein. As shown in FIG. 1, the system 100 may include a host 108 and a memory system 102 having a memory device(s) 104 and a memory controller 106. The host 108 may be a processor (for example, a central processing unit (CPU)) of an electronic device or a system-on-chip (SoC) (for example, an application processor (AP)). The host 108 may be configured to send or receive data to or from the memory device 104.

According to some implementations, the memory controller 106 is coupled to the memory device 104 and the host 108, and is configured to control the memory device 104. The memory controller 106 may manage data stored in the memory device 104 and communicate with the host 108. In some implementations, the memory controller 106 is designed for operating in a low duty-cycle environment like a secure digital (SD) card, a compact flash (CF) card, a universal serial bus (USB) flash drive, or other medium used in an electronic device such as a personal calculator, a digital camera, a mobile phone, etc. In some implementations, the memory controller 106 is designed for operating in a high duty-cycle environment like a SSD or an embedded multi-media-card (eMMCs) used as data storage for a mobile device, such as a smartphone, a tablet computer, a laptop computer, etc., and an enterprise storage array. The memory controller 106 may be configured to control operations of the memory device 104, such as read, erase, and program operations. The memory controller 106 may further be configured to manage various functions with respect to the data stored or to be stored in the memory device 104 including, but not limited to bad-block management, garbage collection, logical-to-physical address conversion, wear leveling, etc. In some implementations, the memory controller 106 is further configured to process an error correction code (ECC) with respect to the data read from or written to the memory device 104. The memory controller 106 may also perform any other suitable functions, for example, the formatting of the memory device 104. The memory controller 106 may communicate with an external device (e.g., the host 108) according to a particular communication protocol. For example, the memory controller 106 may communicate with the external device through at least one of various interface protocols, for example, a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

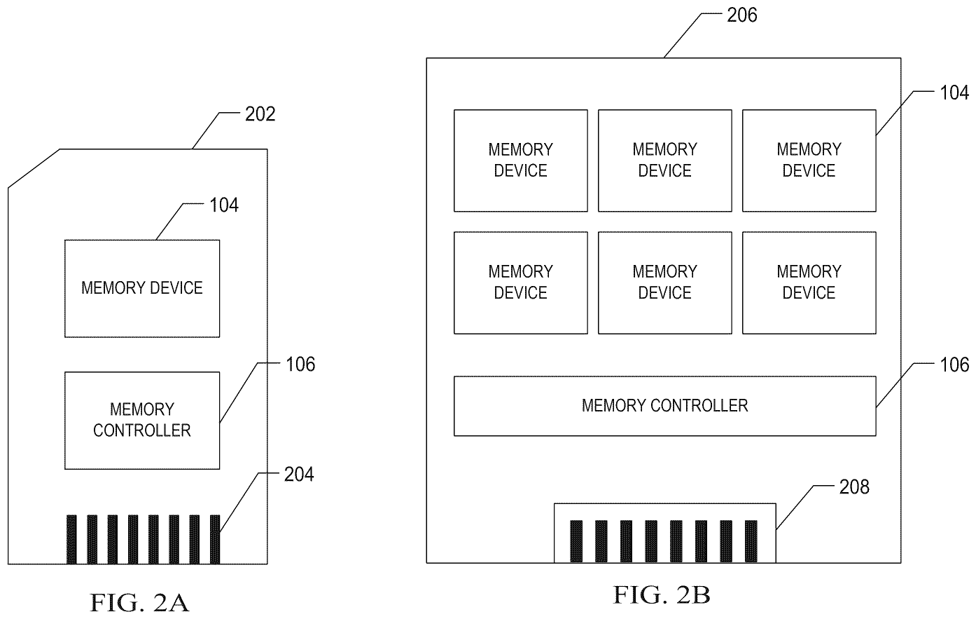

The memory controller 106 and the memory device(s) 104 can be integrated into various types of memory systems, for example, included in the same package (for example, a universal flash storage (UFS) package or an eMMC package). For example, the memory system 102 can be implemented and packaged into different types of end electronic products. In an example as shown in portion (A) of FIG. 2, the memory controller 106 and a single memory device 104 may be integrated into a memory card 202. The memory card 202 may include a PC card (PCMCIA, personal computer memory card international association), a CF card, a smart media (SM) card, a memory stick, a multimedia card (MMC, RS-MMC, MMCmicro), a SD card (SD, miniSD, microSD, SDHC), UFS, etc. The memory card 202 may further include a memory card connector 204 that couples the memory card 202 with a host (e.g., the host 108 in FIG. 1). In another example as shown in portion (B) of FIG. 2, the memory controller 106 and multiple memory devices 104 may be integrated into an SSD 206. The SSD 206 may further include an SSD connector 208 that couples the SSD 206 with a host (e.g., the host 108 in FIG. 1). In some implementations, at least one of a storage capacity or an operation speed of the SSD 206 is greater than that of the memory card 202.

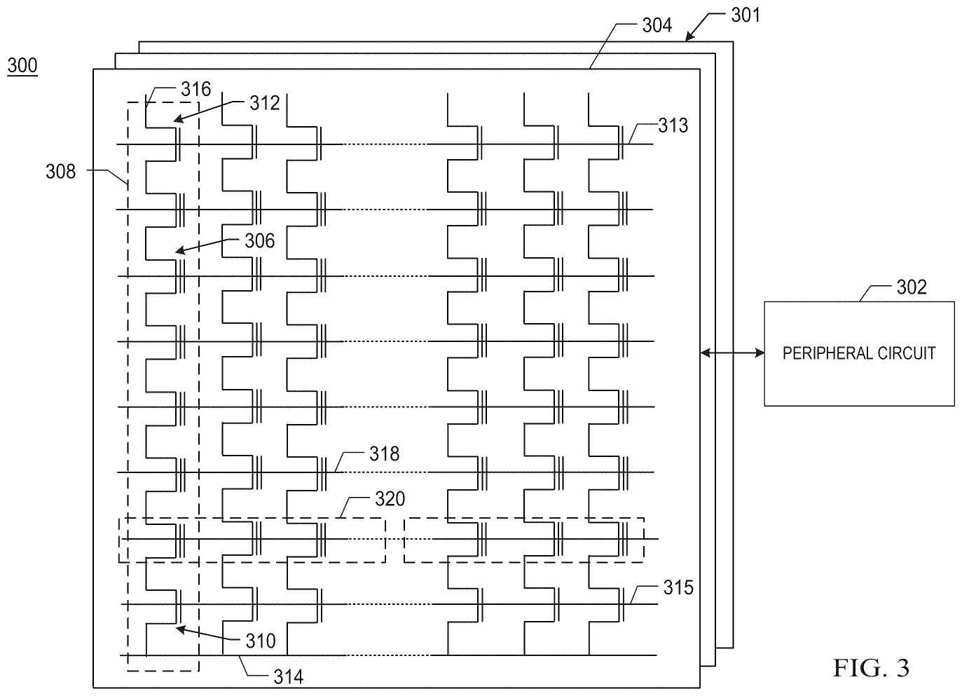

FIG. 3 shows a schematic diagram of an illustrative memory device 300 including a peripheral circuit according to some implementations of the present disclosure. The memory device 300 may be an example of the memory device 104 in FIG. 1. The memory device 300 may include an array 301 of memory cells and a peripheral circuit 302 coupled to the array 301 of memory cells. The array 301 of memory cells may be an array of NAND flash memory cells, where memory cells 306 are provided in the form of an array of NAND memory strings 308 each extending vertically above a substrate (not shown). In some implementations, each NAND memory string 308 includes a plurality of memory cells 306 coupled in series and stacked vertically. Each memory cell 306 may hold a continuous analog value, for example, voltage or charge, that depends on a number of electrons trapped within a region of the memory cell 306. Each memory cell 306 may be a floating-gate memory cell including a floating-gate transistor, or a charge-trap memory cell including a charge-trap transistor.

Each memory cell 306 has any one of a plurality of memory states. In some implementations, each memory cell 306 may be configured to store N-bit data in one of 2^{N} memory states, where N is an integer greater than 1. The 2^{N} memory states include an erased state and 2^{N}−1 non-erased states. In some implementations, each memory cell 306 may include a single-level cell (SLC) that has two possible memory states (levels) and therefore can store one-bit data. For example, a first memory state “0” may correspond to a first range of threshold voltages, and a second memory state “1” may correspond to a second range of threshold voltages. In some implementations, each memory cell 306 may include an xLC that is capable of storing data of more than a single bit with a number of memory states (levels) that is equal to or more than four, for example, but not limited to a multi-level cell (MLC) that has four possible memory states (levels) and therefore can store two-bit data, a triple-level cell (TLC) that has eight possible memory states (levels) and therefore can store three-bit data, a quad-level cell (QLC) that has sixteen possible memory states (levels) and therefore can store four-bit data, etc. In some examples, a program operation is performed by writing one of three possible nominal storage values to the MLC memory cell, to program the MLC memory cell from an erased state to one of three possible program levels (e.g., 01, 10 and 11). A fourth nominal storage value can be used to represent the erased state (e.g., 00).

As shown in FIG. 3, each NAND memory string 308 may further include a source select gate (SSG) transistor 310 at its source end and a drain select gate (DSG) transistor 312 at its drain end. The SSG transistor 310 and the DSG transistor 312 may be configured to activate a selected NAND memory string 308 (a column of the array) during read and program operations. In some implementations, sources of NAND memory strings 308 in the same memory block 304 are coupled through the same source line (SL) 314, for example, a common SL. In other words, according to some implementations, all NAND memory strings 308 in the same memory block 304 have an array common source (ACS). In some implementations, drains of each NAND memory string 308 are coupled to a respective bit line 316 from which data can be read or written via an output bus (not shown). In some implementations, each NAND memory string 308 is configured to be selected or deselected by at least one of: applying a select voltage or a deselect voltage to a gate of the respective DSG transistor 312 via one or more DSG lines 313; or applying a select voltage or a deselect voltage to a gate of the respective SSG transistor 310 via one or more SSG lines 315.

As shown in FIG. 3, the NAND memory strings 308 may be organized into multiple memory blocks 304. Each memory block may have a common source line 314, for example, coupled to the ACS. In some implementations, each memory block 304 may be a basic data unit for erase operations, e.g., erasing all memory cells 306 on the same memory block 304 simultaneously. In order to erase memory cells 306 in a selected memory block 304, a source line 314 coupled to the selected memory block 304 as well as unselected memory blocks 304 in the same plane as the selected memory block 304 can be biased with an erase voltage (EV), for example, a high positive voltage (e.g., 20 V or more). Memory cells 306 of adjacent NAND memory strings 308 can be coupled through word lines 318 that select which row of the memory cells 306 is affected by read and program operations. In some implementations, each word line 318 is coupled to a physical page(s) 320 of the memory cells 306. For example, in the same memory block 304, memory cells 306 coupled to the same word line 318 may constitute a plurality of physical pages 320. The physical page can be a basic data unit for read and program operations. A size of one physical page 320 in bits may relate to a number of NAND memory strings 308 coupled by the word line 318 in one memory block 304. Each word line 318 may include a plurality of control gates (gate electrodes) at individual memory cells 306 in the respective physical page 320 and a gate line coupling the control gates.

The physical page refers to a physical organization structure of actual memory cells in an NAND flash memory, which usually includes multiple memory cells. A logical page is an abstraction layer seen by users or systems or applications, which does not represent a physical unit that actually stores data, but represents a logical organization structure for managing data. In a management process of the NAND flash memory, the logical page usually corresponds to the physical page through a mapping table. The logical page can be a basic data unit for read and program operations.

As shown in FIG. 3, the array 301 of memory cells may include an array of memory cells 306 in multiple rows and multiple columns in each memory block 304. In some implementations, one row of memory cells 306 corresponds to one or more physical pages 320, and one column of memory cells corresponds to one NAND memory string 308. Multiple rows of memory cells 306 may be coupled to a plurality of word lines 318, respectively, and multiple columns of memory cells 306 may be coupled to a plurality of bit lines 316, respectively. The peripheral circuit 302 may be coupled to the array 301 of memory cells through the bit lines 316 and the word lines 318.

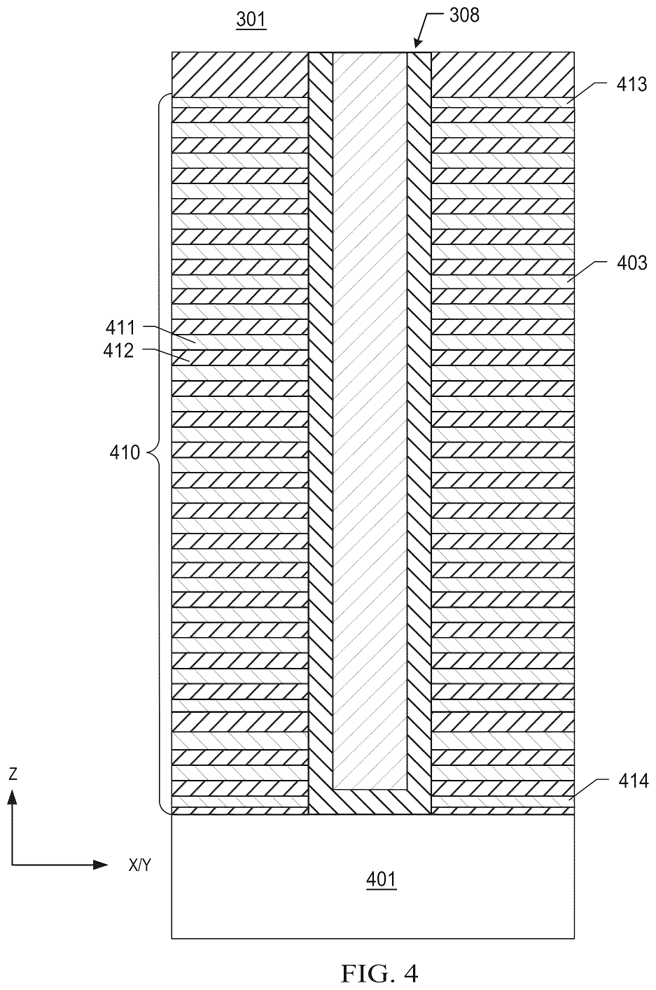

FIG. 4 shows a schematic diagram of a cross-section of an illustrative array 301 of memory cells including an NAND memory string 308 according to some implementations of the present disclosure. As shown in FIG. 4, the NAND memory string 308 may include a stacked structure 410, which includes a plurality of gate layers 411 and a plurality of insulating layers 412 alternately stacked in sequence, and the memory string 308 vertically passing through the gate layers 411 and the insulating layers 412. The gate layers 411 and the insulating layers 412 may be stacked alternately, and two adjacent gate layers 411 are separated by one insulating layer 412. A number of memory cells included in the array 301 of memory cells can be determined based on a number of pairs of gate layers 411 and insulating layers 412 in the stacked structure 410.

A constituent material of the gate layer 411 may include a conductive material. The conductive material include, but is not limited to, tungsten (W), cobalt (Co), copper (Cu), aluminum (Al), polysilicon, doped silicon, silicide, or any combination thereof. In some implementations, each gate layer 411 includes a metal layer, for example, a tungsten layer. In some implementations, each gate layer 411 includes a doped polysilicon layer. Each gate layer 411 may include a control gate surrounding the memory cell. The gate layer 411 at the top of the stacked structure 410 can extend laterally as a top select gate line 413, the gate layer 411 at the bottom of the stacked structure 410 can extend laterally as a bottom select gate line 414, and the gate layers 411 extending laterally between the top select gate line and the bottom select gate line can be used as word line layers 403.

In some implementations, the stacked structure 410 may be disposed on a substrate 401. The substrate 401 may include silicon (e.g., monocrystalline silicon), silicon germanium (SiGe), gallium arsenide (GaAs), germanium (Ge), silicon-on-insulator (SOI), germanium-on-insulator (GOI), or any other suitable material.

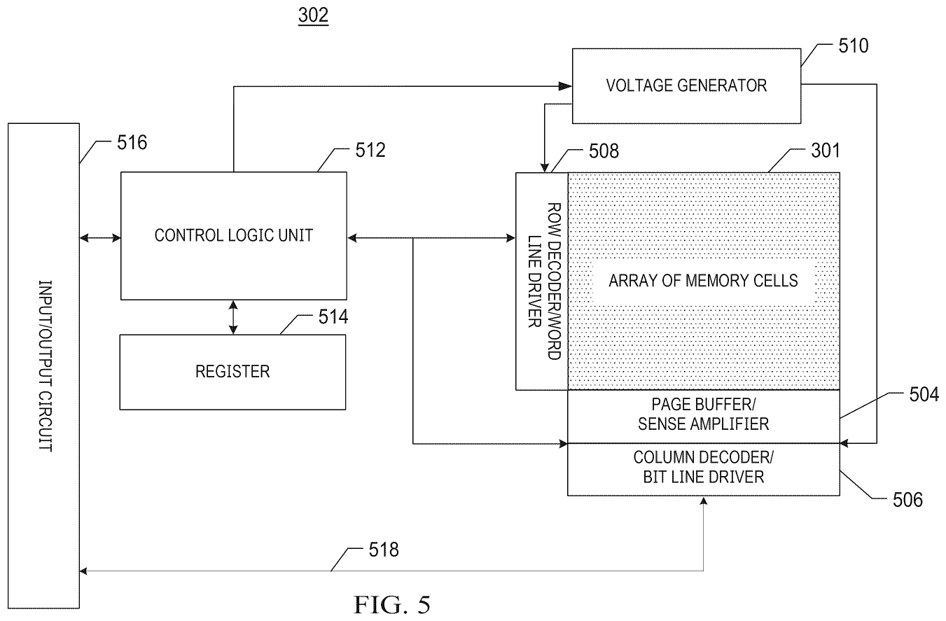

Referring back to FIG. 3, the peripheral circuit 302 can be coupled to the array 301 of memory cells through the bit lines 316, the word lines 318, the source lines 314, the SSG lines 315 and the DSG lines 313. The peripheral circuit 302 may include any suitable analog, digital, and mixed signal circuits for facilitating operations of the array 301 of memory cells by applying and sensing at least one of voltage signals or current signals to and from each target memory cell 306 via the bit lines 316, the word lines 318, the source lines 314, the SSG lines 315, and the DSG lines 313. The peripheral circuit 302 may include various types of peripheral circuits formed using metal-oxide-semiconductor (MOS) technologies. For example, FIG. 5 shows some illustrative peripheral circuits. The peripheral circuit 302 includes a page buffer/sense amplifier 504, a column decoder/bit line driver 506, a row decoder/word line driver 508, a voltage generator 510, a control logic unit 512, a register 514, an input/output circuit 516 and a data bus 518. In some examples, additional peripheral circuits not shown in FIG. 5 may also be included.

The page buffer/sense amplifier 504 may be configured to read and program (write) data from and to the array 301 of memory cells according to control signals from the control logic unit 512. In some examples, the page buffer/sense amplifier 504 may store one page of program data (write data) to be programmed into one physical page 320 of the array 301 of memory cells. In some other examples, the page buffer/sense amplifier 504 may perform program verify operations to ensure that the data has been properly programmed into memory cells 306 coupled to selected word lines 318. In still other examples, the page buffer/sense amplifier 504 may also sense a low power signal from the bit line 316 representing a data bit stored in the memory cell 306, and amplify a small voltage swing to a recognizable logic level in a read operation. The column decoder/bit line driver 506 may be configured to be controlled by the control logic unit 512, and select one or more NAND memory strings 308 by applying bit line voltages generated from the voltage generator 510.

The row decoder/word line driver 508 may be configured to be controlled by the control logic unit 512, and select/deselect the memory blocks 304 of the array 301 of memory cells as well as select/deselect the word lines 318 of the memory blocks 304. The row decoder/word line driver 508 may be further configured to drive the word lines 318 using word line voltages generated from the voltage generator 510. In some implementations, the row decoder/word line driver 508 may also select/deselect and drive the SSG lines 315 and the DSG lines 313. The row decoder/word line driver 508 may be configured to perform an erase operation on the memory cells 306 coupled to the selected word line(s) 318. The voltage generator 510 may be configured to be controlled by the control logic unit 512, and generate the word line voltages (for example, read voltages, program voltages, pass voltages, local voltages, verify voltages, etc.), bit line voltages, and source line voltages to be supplied to the array 301 of memory cells.

The control logic unit 512 may be coupled to each of the peripheral circuits described above, and configured to control operations of each of the peripheral circuits. The register 514 may be coupled to the control logic unit 512, and include a status register, a command register, and an address register for storing status information, command operation codes (OP codes), and command addresses for controlling the operations of each of the peripheral circuits. The input/output circuit 516 may be coupled to the control logic unit 512, and act as a control buffer to buffer and relay a control command received from a host (not shown) to the control logic unit 512, and to buffer and relay the status information received from the control logic unit 512 to the host. The input/output circuit 516 may further be coupled to the column decoder/bit line driver 506 via the data bus 518, and act as a data input/output interface as well as a data buffer to buffer and relay data to or from the array 301 of memory cells.

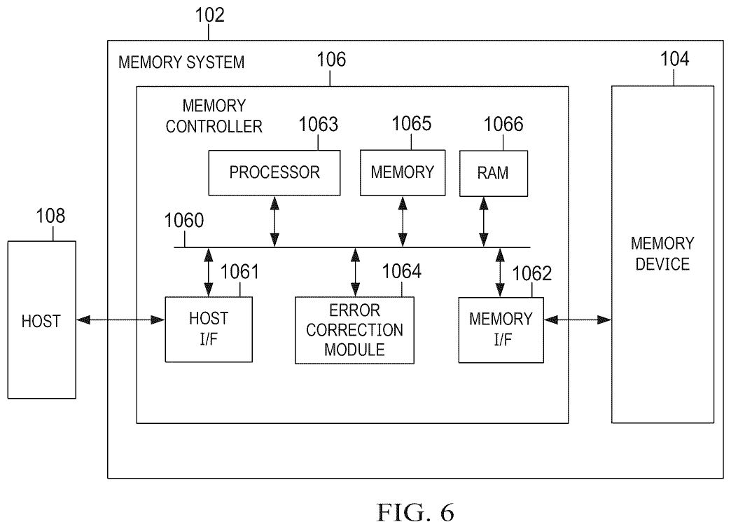

Referring to FIG. 6, FIG. 6 shows a schematic block diagram of a memory controller according to some implementations of the present disclosure. As shown in FIG. 6, the memory controller 106, which may be the memory controller 106 in FIG. 1, may include a processor 1063 (such as but not limited to a central processing unit (CPU), a micro processing unit (MPU), etc.) for controlling general operations of the memory system 102. The memory controller 106 may include a memory 1065 such as, but not limited to a read-only memory (ROM). The processor 1063 may be configured to execute program instructions stored in the memory 1065. The memory controller 106 may include a random access memory (RAM) 1066, in which the processor 1063 may store a work area and memory management information. The memory controller 106 may include a host interface (I/F) 1061 and a memory I/F 1062. The host I/F 1061 may include a data exchange protocol between the memory system 102 and the host 108. The memory I/F 1062 may connect the memory controller 106 with the memory device 104, and may follow an interface protocol to communicate with the memory device 104. For example, ONFI (Open NAND Flash Interface) protocol is an open interface standard for NAND flash memories. The memory controller 106 may instruct the memory I/F 1062 to send commands (e.g., read commands, etc.) to the memory device 104. The form of the commands follows the interface protocol specifications and may include one or more sequences of commands. In addition, the memory controller 106 may include an error correction module 1064 such as, but not limited to an error correction circuit (ECC). The error correction module 1064 can detect an error in data read from the memory device 104 and correct the error. The processor 1063, the memory 1065, the RAM 1066, the host I/F 1061, the memory I/F 1062 and the error correction module 1064 of the memory controller 106 may be coupled together via a bus 1060.

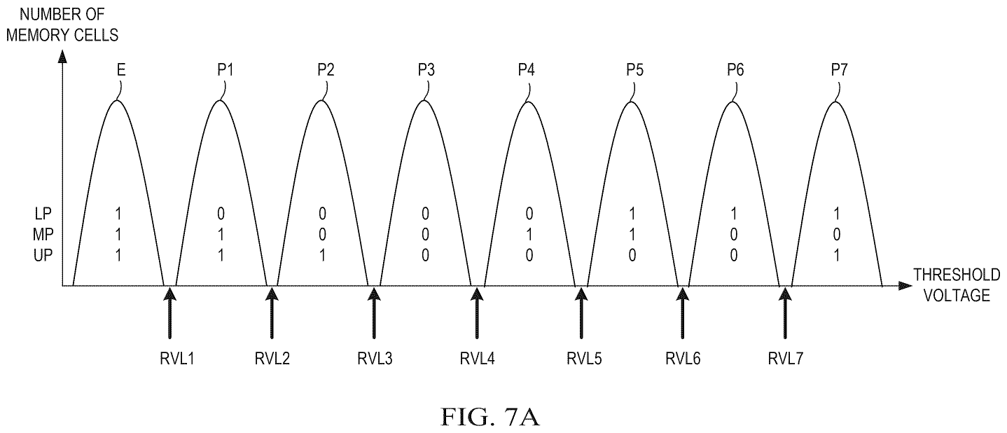

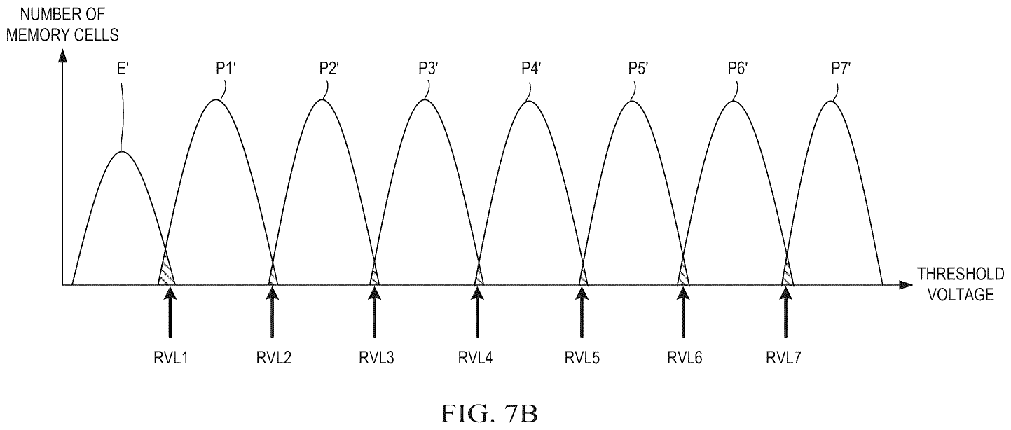

FIG. 7 shows a distribution of threshold voltages of illustrative memory cells of a memory device according to some implementations of the present disclosure. Although the memory cells described below with reference to FIG. 7 are examples of TLCs, the implementations of the present disclosure are not limited to this. For example, the memory cells can be various xLCs, such as MLCs, QLCs, etc., or may be implemented in various other configurations. For example, when each of the memory cells stores N-bit data, the memory cell has 2^{N} states, and the state of the memory cell needs to be determined using 2^{N}−1 read voltages.

Referring to FIG. 7(A), a plurality of memory cells have an erased state E and first to seventh program states P1, P2, P3, P4, P5, P6 and P7. The states of the plurality of memory cells can be determined by a read voltage set including seven (for TLC, N=3, 2^{N}−1=7) read voltages RV1, RV2, RV3, RV4, RV5, RV6 and RV7. Each read voltage RV may have a read voltage level RVL between two states. For example, the read voltage RV1 may have a read voltage level RVL1 between the erased state E and the first program state P1, and so on. The read voltages RV2 to RV7 can have read voltage levels RVL2 to RVL7, respectively.

Under the control of a memory controller (such as the memory controller 106 in FIG. 1), a memory device (such as the memory device 104 in FIG. 1) can use the read voltages RV1 to RV7 to determine the states of the memory cells (such as, the erased state E or the program states P1 to P7), and output read data. For example, when the read voltage RV1 having the read voltage level RVL1 is applied to control electrodes (such as gate electrodes) of the memory cells, memory cells in the erased state E are turned on, and memory cells in the first program state P1 can be turned off. When the memory cell is turned on, a current flows through the memory cell, and when the memory cell is turned off, no current or a small current flows through the memory cell. Therefore, data stored in the memory cell can be determined, distinguished or differentiated according to whether the memory cell is turned on. For example, it can be determined that data “1” is stored when the memory cell is turned on in response to the read voltage applied thereto, and data “0” is stored when the memory cell is turned off in response to the read voltage applied thereto.

In a TLC NAND flash memory, one physical page usually corresponds to three logical pages, namely a lower page (LP), a middle page (MP), and an upper page (UP). In the non-limiting example of FIG. 7(A), the LP corresponds to the read voltages RV1 and RV5, the MP corresponds to the read voltages RV2, RV4, and RV6, and the UP corresponds to the read voltages RV3 and RV7. Certainly, other suitable configurations are also feasible. For example, when a read operation is performed on the memory cells to read data of the lower page, the read voltage RV1 needs to be applied to a word line where the memory cells are present first to distinguish the erased state E from the program states P1 to P7. In some examples, data in memory cells with a threshold voltage of a level lower than the level RVL1 of the read voltage RV1 is read as 1, and data in memory cells with a threshold voltage of a level greater than the level RVL1 of the read voltage RV1 is read as 0. Then, the read voltage RV5 is applied to the word line where the memory cells are present to distinguish the erased state E, the program states P1 to P4, from the program states P5 to P7. Similarly, read operations are performed on the memory cells to read data of the middle page and the upper page, such that data of the corresponding physical page can be obtained through the data of the lower page, the middle page and the upper page.

Compared with the memory cells in the erased state E and the program states P1 to P7 in FIG. 7(A), the distribution of threshold voltages of the memory cells, as shown in FIG. 7(B), may be changed with the passage of time after the memory cells are programmed due to physical characteristics of the memory cells or external factors (such as stimulation, wear, temperature, etc.). For example, the memory cells have a different erased state E′ and different program states P1′, P2′, P3′, P4′, P5′, P6′ and P7′.

The read voltage levels RVL1 to RVL7 of the read voltages RV1 to RV7 are usually determined based on the distribution of threshold voltages immediately after the memory cells are programmed. Therefore, when a data read operation is performed using the read voltage levels RVL1 to RVL7 as they are for respective read voltages RV1 to RV7 after the distribution of threshold voltages has changed, the read data obtained through the data read operation may include errors, and the reliability of the memory device will decrease or deteriorate. For example, a read error may occur on memory cells corresponding to the shaded areas. For example, when a data read operation is performed using the read voltage RV1 having the read voltage level RVL1, even if the memory cells in the shaded area are programmed in the first program state P1′, the memory cells in the shaded area will be incorrectly determined to be in the erased state E′ due to the reduction in threshold voltage.

Therefore, during the life of the memory device, the distribution of threshold voltages of the memory cells may be shifted due to various factors. For example, the distribution of threshold voltages may change due to increased use time, changes in the external environment (for example, changes in temperature), the presence of manufacturing defects, and so on. Finding optimal read voltages is crucial for reducing a raw bit error rate. Especially after the distribution of threshold voltages has changed, it's necessary to re-determine optimal read voltage levels for respective read voltages in order to reduce the raw bit error rate.

According to the characteristic that the distribution of threshold voltages is similar to the normal distribution, for example, for a SLC NAND (in which one physical page usually corresponds to one logical page) corresponding to a single read voltage, a curve with a number of bit flipping on a vertical axis versus a read voltage level on a horizontal axis can be plotted by offsetting a read voltage level for the single read voltage to the left or right (herein, the offsetting is performed along the axis of threshold voltages, offsetting to the left means reducing the level, and offsetting to the right means increasing the level) and recording a number of bit flipping caused by each step of the offsetting. The number of bit flipping can be considered as a number of memory cells whose read value has undergone bit flipping. For example, for the single read voltage, offsetting to the left will cause read values of some memory cells to flip from “1” to “0”, and offsetting to the right will cause read values of some memory cells to flip from “0” to “1”. The number of bit flipping caused by each step can be determined simply by a change in a number of “0” (or “1” ) in the read result of this step compared to a number of “0” (or “1” ) in the read result of the last step. For example, if A “0” were originally read and (A+B) “0” are read after offsetting to the left by one step, then the number of bit flipping caused by this step is B. As a result, a level corresponding to a valley of the plotted curve (e.g., at a minimum of the number of bit flipping) can be determined as the optimal read voltage level for the single read voltage.

With the development of technology, xLC NANDs where each memory cell can store more and more bits of data have emerged, for example, TLC/QLC NANDs. At the same time, threshold voltage windows of these xLC NANDs are getting smaller and smaller, which makes it particularly important to find the optimal read voltage levels for respective read voltages.

The above method of offsetting the read voltage level for the single read voltage of the SLC NAND to find the valley of the number of bit flipping can be performed for each of multiple read voltages corresponding to the xLC NAND to determine its optimal read voltage levels, respectively. However, the more possible memory states of the memory cells, the more read voltages are required, making the above method more time-consuming and laborious.

Levels of the multiple read voltages can be offset simultaneously to find the optimal read voltage levels. For example, for the LP, the read voltage level RVL1 of the read voltage RV1 and the read voltage level RVL5 of the read voltage RV5 can be offset simultaneously at each step. In some implementations, for the read voltage RV1, offsetting the read voltage level RVL1 to the left will cause bit flipping from “1” to “0”, and offsetting the read voltage level RVL1 to the right will cause bit flipping from “0” to “1”. On the contrary, for the read voltage RV5, offsetting the read voltage level RVL5 to the right will cause bit flipping from “1” to “0”, and offsetting the read voltage level RVL5 to the left will cause bit flipping from “0”to “1”.

The bit flipping associated with the offsetting of the read voltage level RVL1 and the bit flipping associated with the offsetting of the read voltage level RVL5 cannot be determined simply by a number of bits “0” (or “1”) in the read result of the LP at each step, respectively. This is because if the read voltage level RVL1 and the read voltage level RVL5 are offset in the same direction (for example, both offset to the left, or both offset to the right) simultaneously at each step, the bit flippings caused by the two are exactly opposite, and a situation where each causes a large number of bit flipping but, as a whole, the number of “0” (or “1” ) remains substantially unchanged may occur. If the read voltage level RVL1 and the read voltage level RVL5 are offset in an opposite direction (for example, one offset to the left and the other offset to the right) simultaneously at each step, the bit flippings caused by the two are the same, and the respective contributions to the changes in the number of “0”s (or “1”s) cannot be distinguished.

One solution is to offset the read voltage level RVL1 and the read voltage level RVL5 in the same direction simultaneously at each step, and then perform data comparison on each individual memory cell to recognize whether the memory cell is from “1” to “0” or from “0” to “1”, thereby determining whether the bit flipping that occurs in the memory cell is due to the offset of the read voltage level RVL1 or the read voltage level RVL5. For example, when being offset to the left simultaneously, the number of bit flipping from “1” to “0” belongs to the read voltage level RVL1, and the number of bit flipping from “0” to “1” belongs to the read voltage level RVL5. When being offset to the right simultaneously, the number of bit flipping from “0” to “1” belongs to the read voltage level RVL1, and the number of bit flipping from “1” to “0” belongs to the read voltage level RVL5. Then, a curve is drawn with the number of bit flipping belonging to the read voltage level RVL1 on a vertical axis versus the read voltage level RVL1 on a horizontal axis and the valley level of the curve is determined as the optimal read voltage level RVL1. And a curve is drawn with the number of bit flipping belonging to the read voltage level RVL5 on a vertical axis versus the read voltage level RVL5 on a horizontal axis and the valley level of the curve is determined as the optimal read voltage level RVL5. This solution requires hardware to support data comparison for each individual memory cell, and a lot of data needs to be cached.

The present disclosure provides a method of operating a memory device which, when finding optimal read levels for respective read voltages corresponding to a certain logical page (as a target page), analyzes a read result of the target page with the help of a read result of another logical page (as an indication page). Specifically, the method obtains the read result of the indication page with a set of read voltage levels corresponding to the indication page, and obtains multiple read results of the target page with multiple sets of read voltage levels corresponding to the target page, respectively. The multiple sets of read voltage levels have offsets from each other. Based on the read result of the indication page, the method can derive bit flipping information associated with each read voltage corresponding to the target page from the multiple read results of the target page, respectively, and then determine its optimal read level. Note that when referring to a read result of a certain page herein, it should be understood as a full-page read result, not a read value of a certain memory cell or read values of certain memory cells therein. Therefore, the method does not depend on the hardware to support the data comparison for each individual memory cell, nor does it need to cache a lot of data.

The following will describe in detail a method of operating a memory device according to various implementations of the present disclosure combined with the drawings. In some implementations, there may be other steps in the actual method, but these other steps are neither discussed herein nor shown in the drawings so as to avoid obscuring the key points of the present disclosure. It should also be understood that the present disclosure will mainly take TLC as an example for illustration, but this does not mean any limitation, and the present disclosure is also applicable to any other xLC.

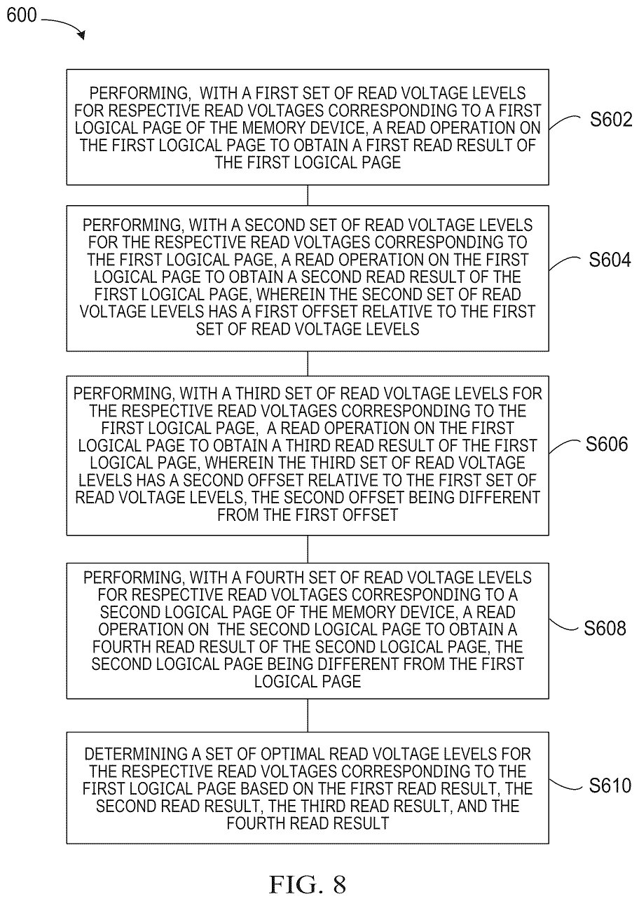

FIG. 8 shows a flowchart of a method 600 of operating a memory device (such as the memory device 104 in FIG. 1) according to some implementations of the present disclosure. As shown in FIG. 8, the method 600 includes steps S602 to S610.

Step S602: performing, with a first set of read voltage levels for respective read voltages corresponding to a first logical page of the memory device, a read operation on the first logical page to obtain a first read result of the first logical page.

Step S604: performing, with a second set of read voltage levels for the respective read voltages corresponding to the first logical page, a read operation on the first logical page to obtain a second read result of the first logical page, wherein the second set of read voltage levels has a first offset relative to the first set of read voltage levels.

Step S606: performing, with a third set of read voltage levels for the respective read voltages corresponding to the first logical page, a read operation on the first logical page to obtain a third read result of the first logical page, wherein the third set of read voltage levels has a second offset relative to the first set of read voltage levels, the second offset being different from the first offset.

Step S608: performing, with a fourth set of read voltage levels for respective read voltages corresponding to a second logical page of the memory device, a read operation on the second logical page to obtain a fourth read result of the second logical page, the second logical page being different from the first logical page.

Step S610: determining a set of optimal read voltage levels for the respective read voltages corresponding to the first logical page based on the first read result, the second read result, the third read result, and the fourth read result.

Herein, the first logical page serves as the target page, and the second logical page serves as the indication page. The first logical page and the second logical page can be different types of logical pages. In some examples, the first logical page is the lower page and the second logical page is the upper page. In some examples, the first logical page is the upper page and the second logical page is the lower page. In some examples, the first logical page is the middle page and the second logical page is the upper page. In some examples, the first logical page is the middle page and the second logical page is the lower page. In some implementations, the respective read voltages corresponding to the first logical page include a first read voltage and a second read voltage, the respective read voltages corresponding to the second logical page include a third read voltage, and the third read voltage may be between the first read voltage and the second read voltage. In some implementations, the respective read voltages corresponding to the second logical page include only one read voltage between the first read voltage and the second read voltage corresponding to the first logical page.

In some implementations, the memory cells that the target page and the indication page each correspond to have similar distributions of threshold voltages, which can be advantageous for improving the accuracy and reliability of using the indication page to help determine the optimal read voltages of the target page. In some implementations, the first logical page and the second logical page may correspond to the same physical page (such as the physical page 320 in FIG. 3) of the memory device. In some implementations, a first physical page corresponding to the first logical page of the memory device and a second physical page corresponding to the second logical page of the memory device may be coupled to the same word line (such as the word line 318 in FIG. 3) of the memory device. For example, the first physical page may be the same as the second physical page, or may be different from the second physical page. In some implementations, a first word line coupled to the first physical page corresponding to the first logical page of the memory device and a second word line coupled to the second physical page corresponding to the second logical page of the memory device may be included in the same set of word lines of the memory device. For example, the first word line may be the same as the second word line, or may be different from the second word line. Referring to FIG. 3, a plurality of memory cells 306 in the NAND memory string 308 are each coupled to a corresponding word line 318. A plurality of word lines 318 coupled to the plurality of memory cells 306 can be divided into multiple groups of word lines according to positions. Each group of word lines includes at least one word line 318. When the memory device is in operation, corresponding word line voltages can be applied to the word lines 318 according to the groups of word lines to improve the performance of the memory device.

In some cases, for example, in the case where the first logical page and the second logical page correspond to the same physical page in the memory device, it's possible that step S602 and step S608 can be combined in one step to be performed. In some implementations, a read operation can be performed on the physical page with a set of read voltage levels (RVL1 to RVL7) for respective read voltages (for example, RV1 to RV7) of the physical page to obtain a read result of the physical page. Then, a read result of each logical page corresponding to the physical page can be determined from the read result of the physical page. It can be understood that this set of read voltage levels (RVL1 to RVL7) includes the first set of read voltage levels for the first logical page (for example, when the first logical page is the lower page, (RVL1₀, RVL5₀)) and the fourth set of read voltage levels for the second logical page (for example, when the second logical page is the upper page, (RVL3₀, RVL7₀)), and the read result of the physical page includes the first read result of the first logical page and the fourth read result of the second logical page. This can be convenient that, for example when the method 600 is re-run subsequently with a third logical page (for example, the middle page) as the target page and the first logical page or the second logical page (for example, the lower page/the upper page) as the indication page, it is possible to omit one read operation for the target page, because an original read result of the third logical page (which may be obtained with a set of read voltage levels (RVL2₀, RVL4₀, RVL6₀)) has been included in the read result of the physical page.

For example, the “offset” (such as the first offset and the second offset) can be characterized by its magnitude and direction (which may also be referred to as “offset magnitude” and “offset direction”, respectively). At each of steps S604 and S606, the read voltage levels of the respective read voltages for the first logical page can be offset simultaneously, which is advantageous for quickly finding the optimal read voltage levels.

For example, the first logical page may correspond to a first read voltage and a second read voltage. In some implementations, the first offset in step S604 is configured such that an offset of a read voltage level from the second set of read voltage levels for the first read voltage relative to a read voltage level from the first set of read voltage levels for the first read voltage has the same offset direction as an offset of a read voltage level from the second set of read voltage levels for the second read voltage relative to a read voltage level from the first set of read voltage levels for the second read voltage, and the second offset in step S606 is configured such that an offset of a read voltage level from the third set of read voltage levels for the first read voltage relative to the read voltage level from the first set of read voltage levels for the first read voltage has the same offset direction as an offset of a read voltage level from the third set of read voltage levels for the second read voltage relative to the read voltage level from the first set of read voltage levels for the second read voltage.

In other words, for each of the first read voltage and the second read voltage, the offset direction of the read voltage level used in step S604 relative to the read voltage level used in step S602 is the same as that of the other, and the offset direction of the read voltage level used in step S606 relative to the read voltage level used in step S602 is also the same as that of the other.

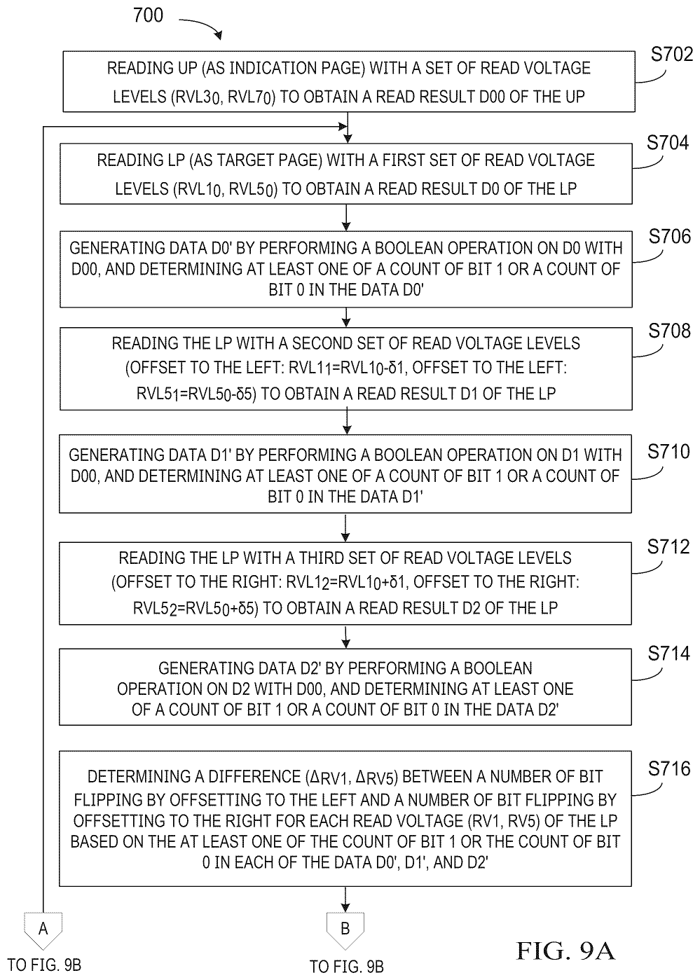

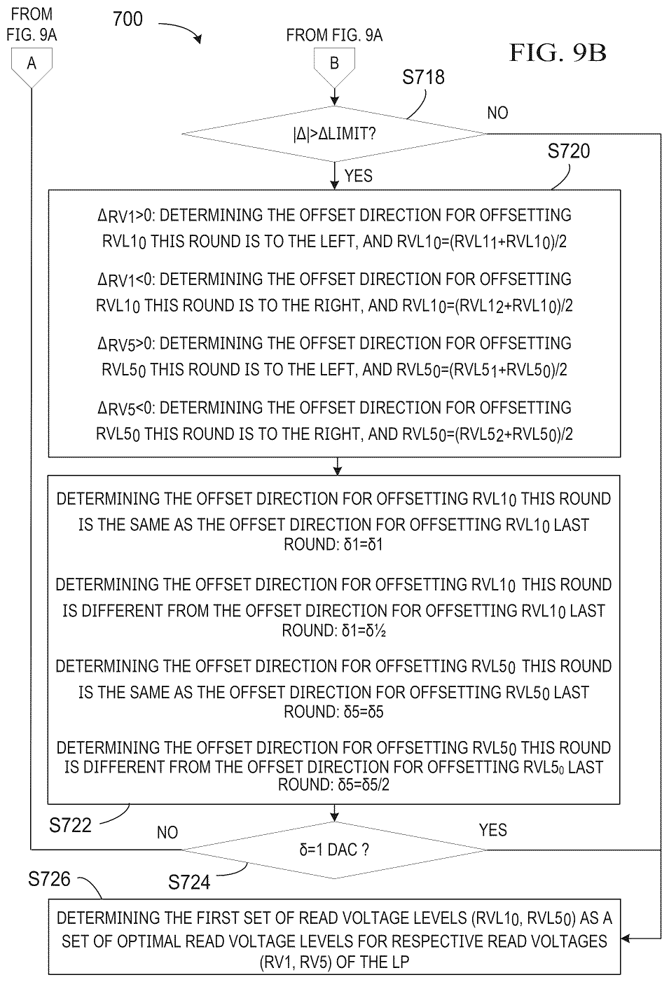

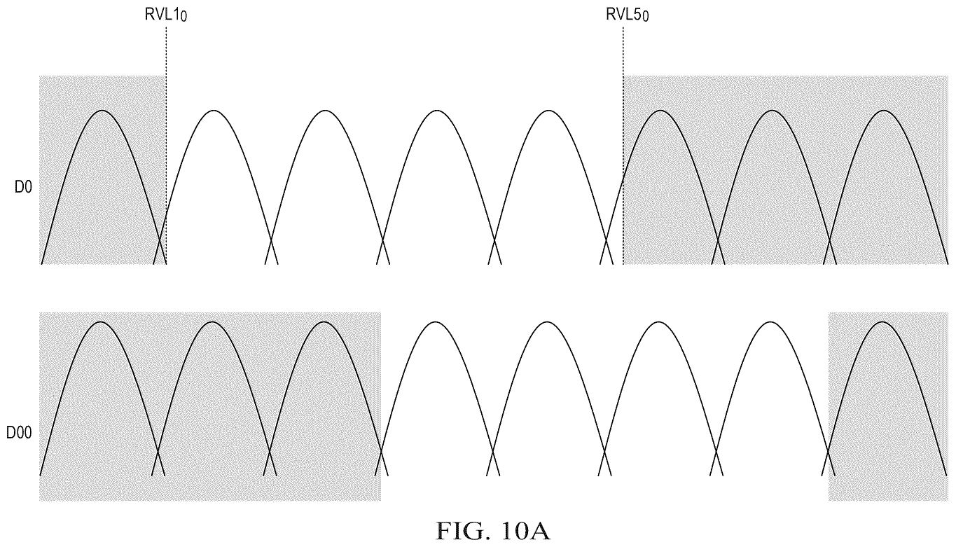

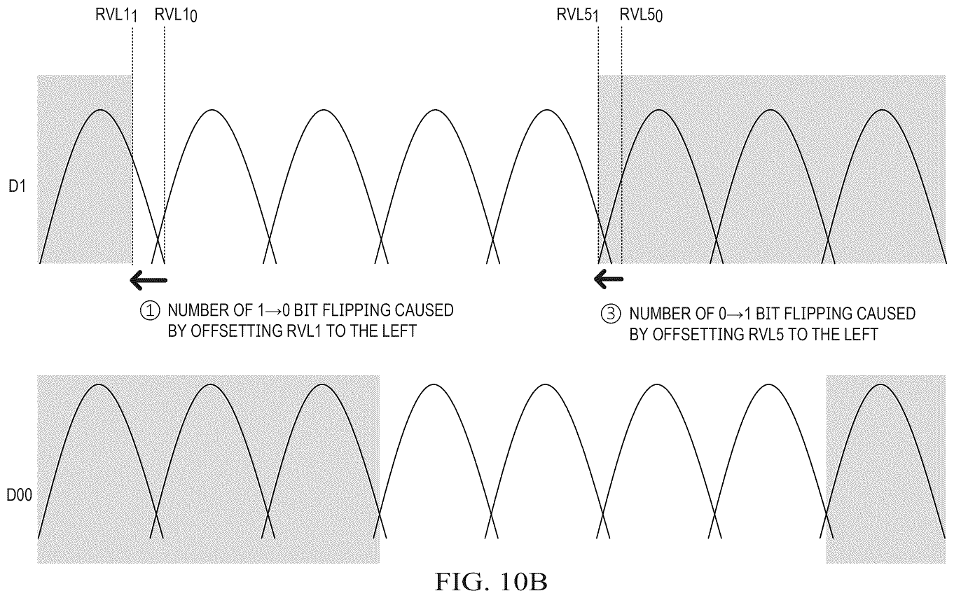

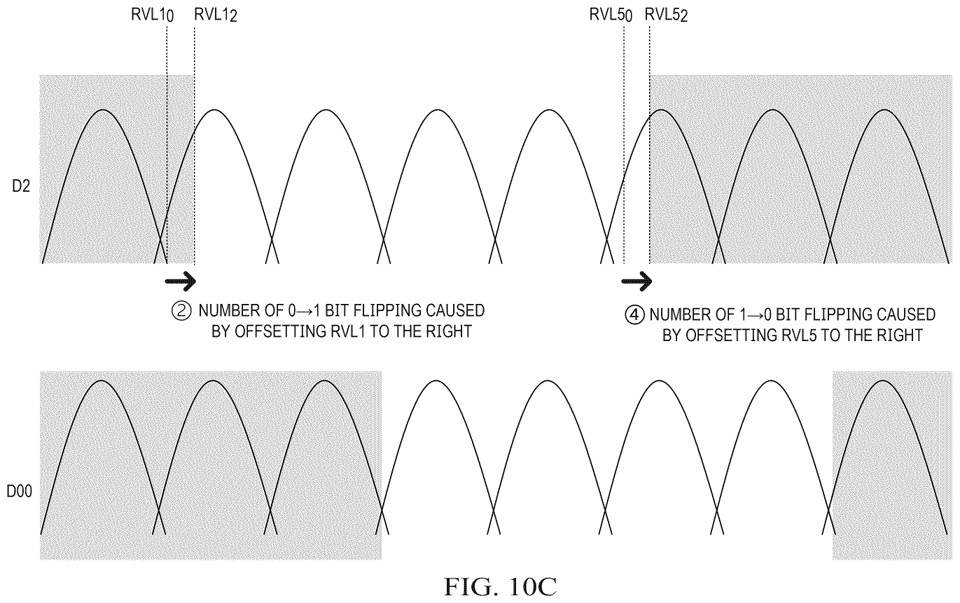

For example, when the first logical page is the lower page, it corresponds to the first read voltage RV1 and the second read voltage RV5. The first set of read voltage levels is denoted as (RVL1₀, RVL5₀), the second set of read voltage levels is denoted as (RVL1₁, RVL5₁), and the third set of read voltage levels is denoted as (RVL1₂, RVL5₂). Then, in the above implementation, the first offset can be configured such that the offset of RVL1₁ relative to RVL1₀ has the same offset direction as the offset of RVL5₁ relative to RVL5₀, and the second offset can be configured such that the offset of RVL1₂ relative to RVL1₀ has the same offset direction as the offset of RVL5₂ relative to RVL5₀. For example, one of the first offset and the second offset may be to offset RVL1 and RVL5 to the left simultaneously, and the other may be to offset RVL1 and RVL5 to the right simultaneously. A more detailed non-limiting example illustration of this will be given later in combination with FIG. 9 and FIG. 10.

In some other implementations, the first offset in step S604 is configured such that the offset of the read voltage level from the second set of read voltage levels for the first read voltage relative to the read voltage level from the first set of read voltage levels for the first read voltage has an opposite offset direction from the offset of the read voltage level from the second set of read voltage levels for the second read voltage relative to the read voltage level from the first set of read voltage levels for the second read voltage, and the second offset in step S606 is configured such that the offset of the read voltage level from the third set of read voltage levels for the first read voltage relative to the read voltage level from the first set of read voltage levels for the first read voltage has an opposite offset direction from the offset of the read voltage level from the third set of read voltage levels for the second read voltage relative to the read voltage level from the first set of read voltage levels for the second read voltage.

In other words, for each of the first read voltage and the second read voltage, the offset direction of the read voltage level used in step S604 relative to the read voltage level used in step S602 is opposite to that of the other, and the offset direction of the read voltage level used in step S606 relative to the read voltage level used in step S602 is also opposite to that of the other.

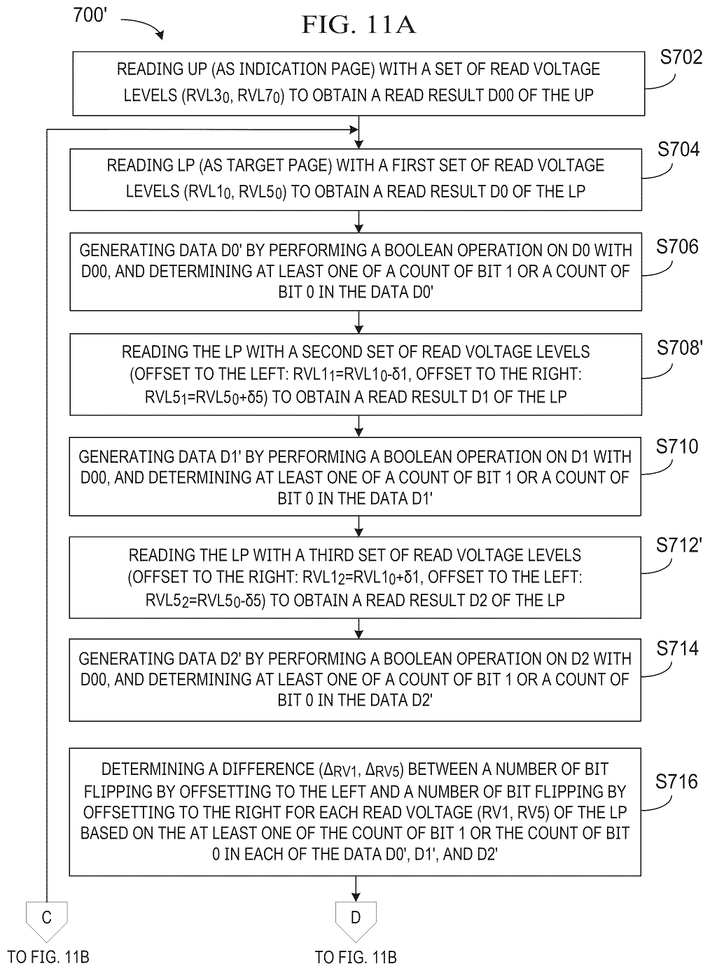

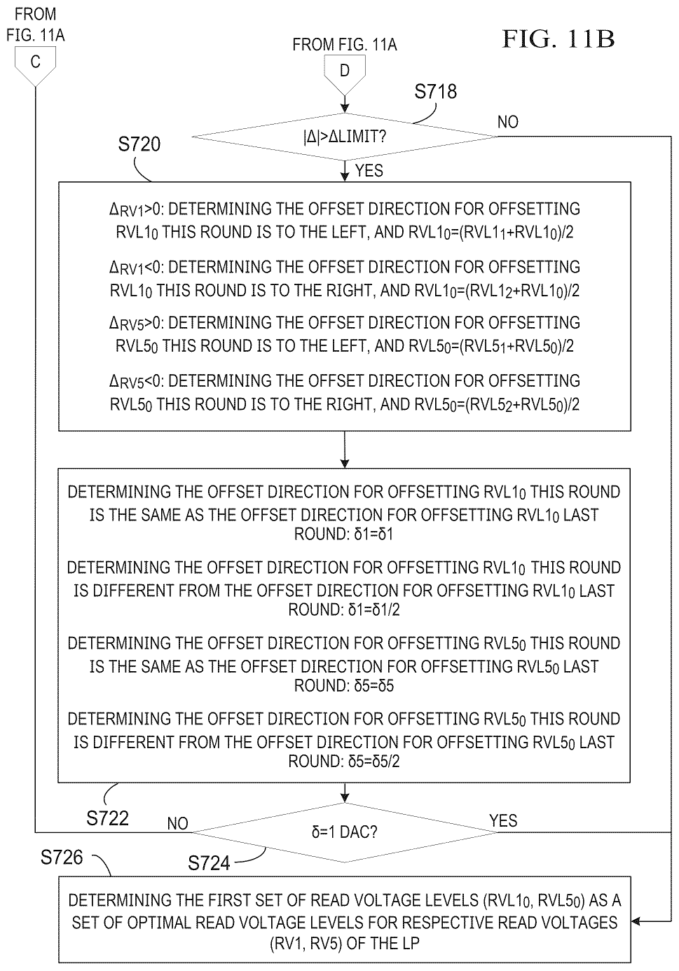

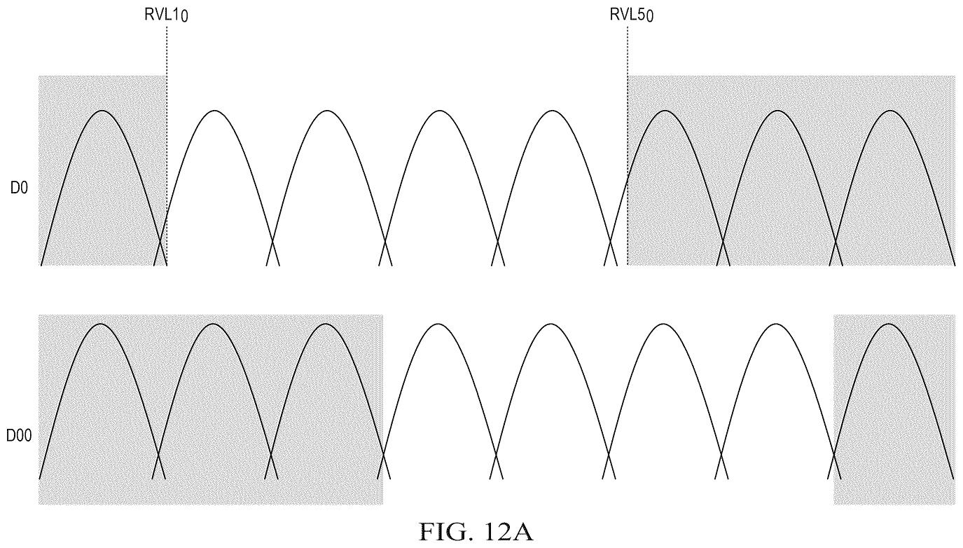

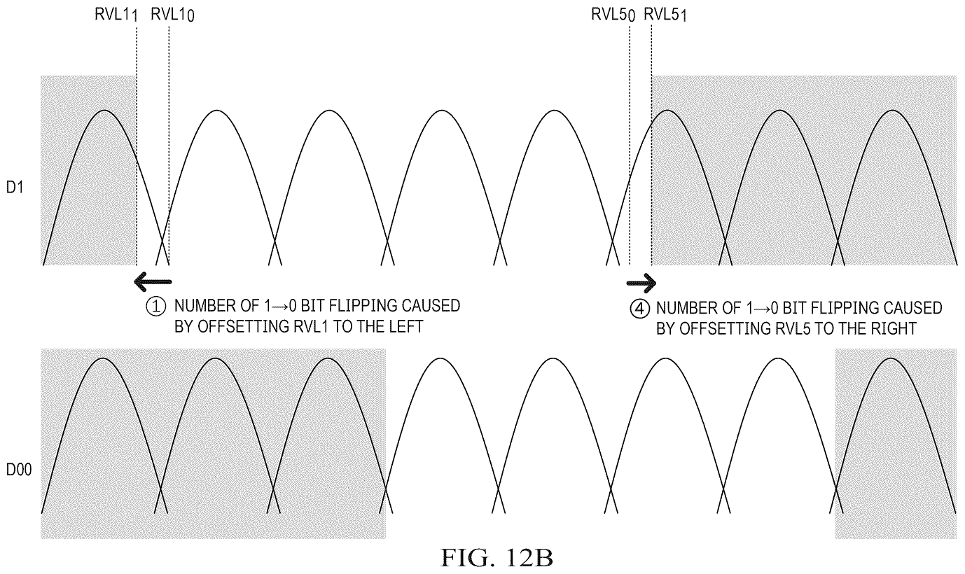

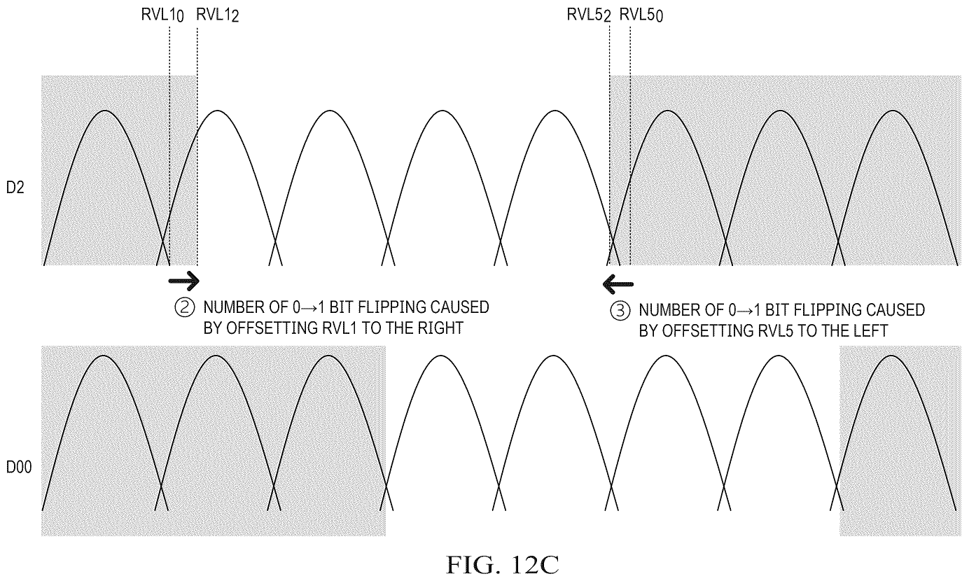

For example, in the above implementation, the first offset can be configured such that the offset of RVL1₁ relative to RVL1₀ has an opposite offset direction from the offset of RVL5₁ relative to RVL5₀, and the second offset can be configured such that the offset of RVL1₂ relative to RVL1₀ has an opposite offset direction from the offset of RVL5₂ relative to RVL5₀. For example, one of the first offset and the second offset can be to offset RVL1 to the left and offset RVL5 to the right simultaneously, and the other can be to offset RVL1 to the right and offset RVL5 to the left simultaneously. A more detailed non-limiting example illustration of this will be given later in combination with FIG. 11 and FIG. 12.

In some cases, the first logical page may correspond to three or more read voltages. For example, the three or more read voltages include the first read voltage and the second read voltage. In such a case, while read voltage levels of two read voltages for the first logical page are offset simultaneously, read voltage levels of other read voltages can be maintained.

In some implementations, the first offset in step S604 is configured such that the offset of the read voltage level from the second set of read voltage levels for the first read voltage relative to the read voltage level from the first set of read voltage levels for the first read voltage has a non-zero offset magnitude, the offset of the read voltage level from the second set of read voltage levels for the second read voltage relative to the read voltage level from the first set of read voltage levels for the second read voltage has a non-zero offset magnitude, and an offset of a read voltage level from the second set of read voltage levels for each read voltage from the three or more read voltages except for the first read voltage and the second read voltage relative to a read voltage level from the first set of read voltage levels for the each read voltage has an offset magnitude of zero.

The second offset in step S606 is configured such that the offset of the read voltage level from the third set of read voltage levels for the first read voltage relative to the read voltage level from the first set of read voltage levels for the first read voltage has a non-zero offset magnitude, the offset of the read voltage level from the third set of read voltage levels for the second read voltage relative to the read voltage level from the first set of read voltage levels for the second read voltage has a non-zero offset magnitude, and an offset of a read voltage level from the third set of read voltage levels for each read voltage from the three or more read voltages except for the first read voltage and the second read voltage relative to the read voltage level from the first set of read voltage levels for the each read voltage has an offset magnitude of zero.

In other words, for each of the first read voltage and the second read voltage, the read voltage level used in step S604 is offset from the read voltage level used in step S602, and the read voltage level used in step S606 is also offset from the read voltage level used in step S602. While for a third read voltage, a read voltage level used in step S604 is not offset from a read voltage level used in step S602, and a read voltage level used in step S606 is not offset from the read voltage level used in step S602 either.

For example, when the first logical page is the middle page, it corresponds to the first read voltage RV2, the second read voltage RV4 and the third read voltage RV6. The first set of read voltage levels is denoted as (RVL2₀, RVL4₀, RVL6₀), the second set of read voltage levels is denoted as (RVL2₁, RVL4₁, RVL6₁), and the third set of read voltage levels is denoted as (RVL2₂, RVL4₂, RVL6₂). Then, in the above implementation, the first offset may, for example, be configured such that the offset of RVL2₁ relative to RVL2₀ as well as the offset of RVL4₁ relative to RVL4₀ has a non-zero offset magnitude, and the offset of RVL6₁ relative to RVL6₀ has an offset magnitude of zero (e.g., RVL2₁ is not equal to RVL2₀, RVL4₁ is not equal to RVL4₀, and RVL6₁ is equal to RVL6₀). The second offset may, for example, be configured such that the offset of RVL2₂ relative to RVL2₀ as well as the offset of RVL4₂ relative to RVL4₀ has a non-zero offset magnitude, and the offset of RVL6₂ relative to RVL6₀ has an offset magnitude of zero (e.g., RVL2₂ is not equal to RVL2₀, RVL4₂ not equal to RVL4₀, and RVL6₂ is equal to RVL6₀). It can be understood that, similar to the aforementioned implementations, the offset of RVL2₁ relative to RVL2₀ and the offset of RVL4₁ relative to RVL4₀ may have the same or opposite offset directions, and the offset of RVL2₂ relative to RVL2₀ and the offset of RVL4₂ relative to RVL4₀ may have the same or opposite offset directions accordingly. Thus, the method 600 can be used first to determine the optimal read voltage levels for the first read voltage RV2 and the second read voltage RV4.

For the third read voltage RV6, the aforementioned method for SLC can be used to determine its optimal read voltage level, and the method 600 can also be used to determine its optimal read voltage level. For example, the method 600 can be re-run, wherein the first offset may, for example, be configured such that the offset of RVL4₁ relative to RVL4₀ as well as the offset of RVL6₁ relative to RVL6₀ has a non-zero offset magnitude and the offset of RVL2₁ relative to RVL2₀ has an offset magnitude of zero (e.g., RVL4₁ is not equal to RVL4₀, RVL6₁ is not equal to RVL6₀, and RVL2₁ is equal to RVL2₀). The second offset may, for example, be configured such that the offset of RVL4₂ relative to RVL4₀ as well as the offset of RVL6₂ relative to RVL6₀ has a non-zero offset magnitude and the offset of RVL2₂ relative to RVL2₀ has an offset magnitude of zero(e.g., RVL4₂ is not equal to RVL4₀, RVL6₂ not equal to RVL6₀, and RVL2₂ is equal to RVL2₀). It can be understood that, similar to the aforementioned implementations, the offset of RVL4₁ relative to RVL4₀ and the offset of RVL6₁ relative to RVL6₀ may have the same or opposite offset directions, and the offset of RVL4₂ relative to RVL4₀ and the offset of RVL6₂ relative to RVL6₀ may have the same or opposite offset directions accordingly. Thus, the method 600 can be used again to determine the optimal read voltage levels for the second read voltage RV4 and the third read voltage RV6.

In some implementations, the first offset and the second offset can have the same offset magnitudes.

In some examples, the first offset and the second offset are configured such that the offset of the read voltage level from the second set of read voltage levels for the first read voltage relative to the read voltage level from the first set of read voltage levels for the first read voltage and the offset of the read voltage level from the third set of read voltage levels for the first read voltage relative to the read voltage level from the first set of read voltage levels for the first read voltage have the same offset magnitudes. Additionally or alternatively, in some examples, the offset of the read voltage level from the second set of read voltage levels for the second read voltage relative to the read voltage level from the first set of read voltage levels for the second read voltage and the offset of the read voltage level from the third set of read voltage levels for the second read voltage relative to the read voltage level from the first set of read voltage levels for the second read voltage have the same offset magnitudes.

For example, when the first logical page is the lower page, it corresponds to the first read voltage RV1 and the second read voltage RV5. The first set of read voltage levels is denoted as (RVL1₀, RVL5₀), the second set of read voltage levels is denoted as (RVL1₁, RVL5₁), and the third set of read voltage levels is denoted as (RVL1₂, RVL5₂). Then, in the above examples, the offset of RVL1₁ relative to RVL1₀ may have the same offset magnitude as that of the offset of RVL1₂ relative to RVL1₀, and the offset of RVL5₁ relative to RVL5₀ may have the same offset magnitude as that of the offset of RVL5₂ relative to RVL5₀. Thus, for each read voltage, the first offset and the second offset occur symmetrically, which may be advantageous for quickly finding the optimal read voltage level for it.

In some other implementations, the first offset and the second offset may also have different offset magnitudes. In some examples, the first offset and the second offset are configured such that the offset of the read voltage level from the second set of read voltage levels for the first read voltage relative to the read voltage level from the first set of read voltage levels for the first read voltage and the offset of the read voltage level from the third set of read voltage levels for the first read voltage relative to the read voltage level from the first set of read voltage levels for the first read voltage have different offset magnitudes. Additionally or alternatively, in some examples, the offset of the read voltage level from the second set of read voltage levels for the second read voltage relative to the read voltage level from the first set of read voltage levels for the second read voltage and the offset of the read voltage level from the third set of read voltage levels for the second read voltage relative to the read voltage level from the first set of read voltage levels for the second read voltage have different offset magnitudes.

The offset magnitude of the first offset and the offset magnitude of the second offset can be configured separately for each read voltage according to its specific requirement. For example, the first offset can be configured such that the offset of the read voltage level from the second set of read voltage levels for the first read voltage relative to the read voltage level from the first set of read voltage levels for the first read voltage and the offset of the read voltage level from the second set of read voltage levels for the second read voltage relative to the read voltage level from the first set of read voltage levels for the second read voltage have the same or different offset magnitudes. Similarly, the second offset can be configured such that the offset of the read voltage level from the third set of read voltage levels for the first read voltage relative to the read voltage level from the first set of read voltage levels for the first read voltage and the offset of the read voltage level from the third set of read voltage levels for the second read voltage relative to the read voltage level from the first set of read voltage levels for the second read voltage have the same or different offset magnitudes.

Step S610 may include determining, based on the first read result, the second read result, the third read result, and the fourth read result, whether to offset the first set of read voltage levels so as to obtain the set of optimal read voltage levels. In some implementations, the first set of read voltage levels is determined as the set of optimal read voltage levels in response to determining not to offset the first set of read voltage levels so as to obtain the set of optimal read voltage levels based on the first read result, the second read result, the third read result, and the fourth read result. In some implementations, an offset direction and an offset value for offsetting the first set of read voltage levels are determined based on the first read result, the second read result, the third read result, and the fourth read result in response to determining to offset the first set of read voltage levels so as to obtain the set of optimal read voltage levels based on the first read result, the second read result, the third read result, and the fourth read result; a first offset magnitude to be applied to the first offset and a second offset magnitude to be applied to the second offset are determined based on the determined offset direction. Herein, the “offset value” may refer to a value that has been subjected to the offsetting.

In some examples, step S610 may include determining the set of optimal read voltage levels for the respective read voltages corresponding to the first logical page based on first data generated from the first read result and the fourth read result, second data generated from the second result and the fourth read result, and third data generated from the third read result and the fourth read result. In some examples, the first data, the second data, and the third data are generated by performing Boolean operations on the first read result, the second read result, and the third read result with the fourth read result, respectively. Boolean operations include, for example, AND operations, OR operations, XOR operations, NOT operations, or combinations thereof, etc. In some examples, the first data, the second data, and the third data are generated by performing addition operations without carry on the first read result, the second read result, and the third read result with the fourth read result, respectively. In some examples, the first data, the second data, and the third data are generated by performing multiplication operations on the first read result, the second read result, and the third read result with the fourth read result, respectively.

For example, at least one of a count of bit 1 or a count of bit 0 in each of the first to third data may be determined. Then, for each read voltage corresponding to the first logical page, a difference between a number of bit flipping caused by the first offset and a number of bit flipping caused by the second offset is determined based on the at least one of the count of bit 1 or the count of bit 0. The set of optimal read voltage levels for the respective read voltages corresponding to the first logical page can be determined based on the difference. In some implementations, the first set of read voltage levels is determined as the set of optimal read voltage levels in response to determining that an absolute value of the difference does not exceed a preset difference threshold. In some implementations, the offset direction and the offset value for offsetting the first set of read voltage levels are determined based on a sign of the difference in response to determining that the absolute value of the difference exceeds the preset difference threshold. The preset difference threshold can be set specifically according to the actual situation. In particular, the preset difference threshold for each read voltage can be configured separately according to its specific requirement.

For example, the difference being positive may indicate that the offset direction of the first offset should be used as the offset direction for offsetting the first set of read voltage levels, and accordingly, the offset value can be determined as a value between the first set of read voltage levels and the second set of read voltage levels (for example, but not limited to a half of a sum of the two, this bisection method is advantageous for quickly finding the optimal read voltage level). The difference being negative may indicate that the offset direction of the second offset should be used as the offset direction for offsetting the first set of read voltage levels, and accordingly, the offset value can be determined as a value between the first set of read voltage levels and the third set of read voltage levels (for example, but not limited to a half of a sum of the two, this bisection method is advantageous for quickly finding the optimal read voltage level). It can be understood that, when the difference is defined in the opposite way as a difference between the number of bit flipping caused by the second offset and the number of bit flipping caused by the first offset, the meaning indicated by its sign is also reversed accordingly.

In some examples, the first offset magnitude to be applied to the first offset and the second offset magnitude to be applied to the second offset can be determined based on the determined offset direction by the following operations. When the determined offset direction is the same as an offset direction used to obtain the current first set of read voltage levels, the offset magnitudes currently used for the first offset and the second offset can continue to be used. When the determined offset direction is opposite to the offset direction used to obtain the current first set of read voltage levels, the first offset magnitude and the second offset magnitude can be reduced relative to the offset magnitudes currently used for the first offset and the second offset, for example, but not limited to, reduced to a half of the original magnitude (this bisection method is advantageous for quickly finding the optimal read voltage level).

In some implementations, the first set of read voltage levels is determined as the set of optimal read voltage levels in response to determining that the first offset magnitude and the second offset magnitude do not exceed a preset offset magnitude threshold. The preset offset magnitude threshold can be set specifically according to the actual situation, and corresponding preset offset magnitude thresholds can also be set for the first offset magnitude and the second offset magnitude, respectively (which can be the same or different). In particular, the preset offset magnitude threshold for each read voltage can be configured separately according to its specific requirement. As a non-limiting example, the preset offset magnitude threshold can be taken as one minimum level variable unit of a digital-to-analog converter (1 DAC). It can be determined that when the first offset magnitude and the second offset magnitude are equal to 1 DAC, the optimal read voltage level has been found with sufficient accuracy.

In some implementations, in response to determining that the first offset magnitude and the second offset magnitude exceed the preset offset magnitude threshold: a read operation is performed on the first logical page with the first set of read voltage levels updated based on the offset value for the respective read voltages corresponding to the first logical page to re-obtain the first read result of the first logical page; a read operation is performed on the first logical page with the second set of read voltage levels updated based on the offset value and the first offset magnitude for the respective read voltages corresponding to the first logical page to re-obtain the second read result of the first logical page; a read operation is performed on the first logical page with the third set of read voltage levels updated based on the offset value and the second offset magnitude for the respective read voltages corresponding to the first logical page to re-obtain the third read result of the first logical page; and the set of optimal read voltage levels is determined for the respective read voltages corresponding to the first logical page based on the re-obtained first read result, the re-obtained second read result, the re-obtained third read result and the fourth read result (obtained in step S608). For example, the process of determining the set of optimal read voltage levels based on the re-obtained first read result, the re-obtained second read result, the re-obtained third read result and the fourth read result may be similar to the previous process of determining the set of optimal read voltage levels based on the first read result, the second read result, the third read result and the fourth read result, which are not repeated herein. Through such iteration, the updated first set of read voltage levels can continuously approach until the optimal read voltage levels are reached.

For non-limiting illustrative purposes, the following describes various illustrative processes in which the method 600 of operating a memory device according to an implementation of the present disclosure is applied, in conjunction with FIG. 9 to FIG. 12.

FIG. 9 shows a flowchart of an illustrative process 700 in which the method 600 of operating a memory device according to an implementation of the present disclosure is applied. FIG. 10 shows a schematic diagram of bit flipping caused by offsetting read voltage levels in the process of FIG. 9. In FIG. 10, a memory cell in the gray area has a read value of “1”, and a memory cell in the white area has a read value of “0”.

As shown in FIG. 9, the UP (as the indication page) is read with a set of read voltage levels (RVL3₀, RVL7₀) to obtain a read result D00 of the UP (S702), and the LP (as the target page) is read with a first set of read voltage levels (RVL1₀, RVL5₀) to obtain a read result D0 of the LP (S704). For example, the read voltage levels RVL1₀, RVL3₀, RVL5₀, and RVL7₀ can be default values obtained through table look-up, or values determined by the last run of the method 600, and so on. Data D0′ is generated by performing a Boolean operation on D0 with D00, and at least one of a count of bit 1 or a count of bit 0 in the data D0′ are determined (S706).

The LP is read with a second set of read voltage levels (RVL1₁=RVL₁₀-δ1, RVL5₁=RVL5₀-δ5) to obtain a read result D1 of the LP (S708). Each read voltage level from the second set of read voltage levels is offset to the left relative to a corresponding read voltage level from the first set of read voltage levels. δ1 is an offset magnitude δ for RVL1, and δ5 is an offset magnitude δ for RVL5. Data D1′ is generated by performing a Boolean operation on D1 with D00, and at least one of a count of bit 1 or a count of bit 0 in the data D1′ are determined (S710).

The LP is read with a third set of read voltage levels (RVL1₂=RVL1₀+δ1, RVL5₂=RVL5₀+δ5) to obtain a read result D2 of LP (S712). Each read voltage level from the third set of read voltage levels is offset to the right relative to a corresponding read voltage level from the first set of read voltage levels. For RV1 and RV5, respectively, offsetting to the right here is symmetrical with the previous offsetting to the left. In other words, they have the same offset magnitudes. Data D2′ is generated by performing a Boolean operation on D2 with D00, and at least one of a count of bit 1 or a count of bit 0 in the data D2′ are determined (S714).

Based on the at least one of the count of bit 1 or the count of bit 0 in each of the data D0′,D1′, and D2′, a difference Δ (Δ_{RV1}, Δ_{RV5}) between a number of bit flipping by offsetting to the left and a number of bit flipping by offsetting to the right is determined for each read voltage (RV1, RV5) of the LP (S716).

It's determined whether absolute values of Δ_{RV1} and Δ_{RV5} exceed corresponding thresholds Δₗᵢₘᵢₜ (Δₗᵢₘᵢₜ₁, Δₗᵢₘᵢₜ₅), respectively (S718). If Δ does not exceed Δₗᵢₘᵢₜ, the first set of read voltage levels (RVL1₀, RVL5₀) is determined as a set of optimal read voltages for respective read voltages (RV1, RV5) of the LP (S726). For example, if Δ_{RV1} does not exceed Δₗᵢₘᵢₜ₁, then RVL1₀ is determined as the optimal read voltage level for RV1, and if Δ_{RV5} does not exceed Δₗᵢₘᵢₜ₅, then RVL5₀ is determined as the optimal read voltage level for RV5. It can be understood that, if the optimal read voltage level for one of RV1 and RV5 is found before that for another, the one can be fixed at its optimal read voltage level, and only the level for the other is adjusted in subsequent iterations until the optimal read voltage level for the other is also found.

If Δ exceeds Δₗᵢₘᵢₜ, then an offset direction and an offset value for offsetting the first set of read voltage levels this round can be determined according to a sign of Δ (S720). For example, if Δ_{RV1}>0, then it is determined that the offset direction for offsetting RVL1₀ this round is to the left, and RVL1₀=(RVL1₁+RVL1₀)/2. If Δ_{RV1}<0, then it is determined that the offset direction for offsetting RVL1₀ this round is to the right, and RVL1₀=(RVL1₂+RVL1₀)/2. Additionally, if Δ_{RV5}>0, then it is determined that the offset direction for offsetting RVL5₀ this round is to the left, and RVL5₀=(RVL5₁+RVL5₀)/2. If Δ_{RV5}<0, then it is determined that the offset direction for offsetting RVL5₀ this round is to the right, and RVL5₀=(RVL5₂+RVL5₀)/2.

Based on the determined offset direction, a value of the offset magnitude δ in the next round can be determined (S722). For example, if it is determined that the offset direction for offsetting RVL1₀ this round is the same as the offset direction for offsetting RVL1₀ last round, then δ1=δ1. If it is determined that the offset direction for offsetting RVL1₀ this round is different from the offset direction for offsetting RVL1₀ last round, then δ1=δ1/2. Additionally, if it is determined that the offset direction for offsetting RVL5₀ this round is the same as the offset direction for offsetting RVL5₀ last round, then δ5=δ5. If it is determined that the offset direction for offsetting RVL5₀ this round is different from the offset direction for offsetting RVL5₀ last round, then δ5=δ5/2.

It's determined whether δ1 and δ5 are equal to 1 DAC, respectively (S724). If δ is equal to 1 DAC, the first set of read voltage levels (RVL1₀, RVL5₀) is determined as the set of optimal read voltage levels for the respective read voltages (RV1, RV5) of the LP (S726). For example, if δ1 is equal to 1 DAC, then RVL1₀ is determined as the optimal read voltage level for RV1. If δ5 is equal to 1 DAC, then RVL5₀ is determined as the optimal read voltage level for RV5. It can be understood that, if the optimal read voltage level for one of RV1 and RV5 is found before that for another, the one can be fixed at its optimal read voltage level, and only the level for the other is adjusted in subsequent iterations until the optimal read voltage level for the other is also found.

If δ is not equal to 1 DAC, then it is possible to return to S704 for a next round of iteration.

Referring to FIG. 10, (A) corresponds to D0 and D00, (B) corresponds to D1 and D00, and (C) corresponds to D2 and D00.

In an example implementation, it is determined that the count of bit 1 in (D00 AND D0) is a, the count of bit 1 in (D00 AND D1) is b, the count of bit 1 in (D00 AND D2) is c, the count of bit 0 in (D00 OR D0) is d, the count of bit 0 in (D00 OR D1) is e, and the count of bit 0 in (D00 OR D2) is f. Then it is determined that the number of 1→0 bit flipping caused by offsetting RVL1 to the left is \textcircled{1}=a−b, the number of 0→1 bit flipping caused by offsetting RVL1 to the right is \textcircled{2}=c−a, the number of 0→1 bit flipping caused by offsetting RVL5 to the left is \textcircled{3}=d−e, and the number of 1→0 bit flipping caused by offsetting RVL5 to the right is \textcircled{4}=f−d, thereby determining Δ_{RV1}=\textcircled{1}−\textcircled{2}, and Δ_{RV5}=\textcircled{3}−\textcircled{4}.

In another example implementation, it is determined that the count of bit 1 in D0 is a, the count of bit 1 in D1 is b, the count of bit 1 in D2 is c, the count of bit 1 in (D00 XOR D0) is d, the count of bit 1 in (D00 XOR D1) is e, and the count of bit 1 in (D00 XOR D2) is f. Then it is determined that the number of 1→0 bit flipping caused by offsetting RVL1 to the left is \textcircled{1}=(a−b+d−e)/2, the number of 0→1 bit flipping caused by offsetting RVL1 to the right is \textcircled{2}=(f−d−a+c)/2, the number of 0→1 bit flipping caused by offsetting RVL5 to the left is \textcircled{3}=(d−e−a+b)/2, and the number of 1→0 bit flipping caused by offsetting RVL5 to the right is \textcircled{4}=(a−c+f−d)/2, thereby determining Δ_{RV1}=\textcircled{1}−\textcircled{2}, and Δ_{RV5}=\textcircled{3}−\textcircled{4}.

It is possible to use the NOT operation to replace the count of bit 1 in the aforementioned example implementations with the count of bit 0, or vice versa.

In an example implementation, it is determined that the count of bit 0 in [NOT (D00 AND D0)] is a, the count of bit 0 in [NOT (D00 AND D1)] is b, the count of bit 0 in [NOT (D00 AND D2)] is c, the count of bit 0 in (D00 OR D0) is d, the count of bit 0 in (D00 OR D1) is e, and the count of bit 0 in (D00 OR D2) is f. Then it is determined that the number of 1→0 bit flipping caused by offsetting RVL1 to the left is \textcircled{1}=a−b, the number of 0→1 bit flipping caused by offsetting RVL1 to the right is \textcircled{2}=c−a, the number of 0→1 bit flipping caused by offsetting RVL5 to the left is \textcircled{3}=d−e, and the number of 1→0 bit flipping caused by offsetting RVL5 to the right is \textcircled{4}=f−d, thereby determining Δ_{RV1}=\textcircled{1}−\textcircled{2}, and Δ_{RV5}=\textcircled{3}−\textcircled{4}.

In another example implementation, it is determined that the count of bit 1 in (D00 AND D0) is a, the count of bit 1 in (D00 AND D1) is b, the count of bit 1 in (D00 AND D2) is c, the count of bit 1 in [NOT (D00 OR D0)] is d, the count of bit 1 in [NOT (D00 OR D1)] is e, and the count of bit 1 in [NOT (D00 OR D2)] is f. Then it is determined that the number of 1→0 bit flipping caused by offsetting RVL1 to the left is \textcircled{1}=a−b, the number of 0→1 bit flipping caused by offsetting RVL1 to the right is \textcircled{2}=c−a, the number of 0→1 bit flipping caused by offsetting RVL5 to the left is \textcircled{3}=d−e, and the number of 1→0 bit flipping caused by offsetting RVL5 to the right is \textcircled{4}=f−d, thereby determining Δ_{RV1}=\textcircled{1}−\textcircled{2}, and Δ_{RV5}=\textcircled{3}−\textcircled{4}.

In still another example implementation, it is determined that the count of bit 1 in D0 is a, the count of bit 1 in D1 is b, the count of bit 1 in D2 is c, the count of bit 0 in [NOT (D00 XOR D0)] is d, the count of bit 0 in [NOT (D00 XOR D1)] is e, and the count of bit 0 in [NOT (D00 XOR D2)] is f. Then it is determined that the number of 1→0 bit flipping caused by offsetting RVL1 to the left is \textcircled{1}=(a−b+d−e)/2, the number of 0→1 bit flipping caused by offsetting RVL1 to the right is \textcircled{2}=(f−d−a+c)/2, the number of 0→1 bit flipping caused by offsetting RVL5 to the left is \textcircled{3}=(d−e−a+b)/2, and the number of 1→0 bit flipping caused by offsetting RVL5 to the right is \textcircled{4}=(a−c+f−d)/2, thereby determining Δ_{RV1}=\textcircled{1}−\textcircled{2}, and Δ_{RV5}=\textcircled{3}−\textcircled{4}.

FIG. 11 shows a flowchart of another illustrative process 700′ in which the method 600 of operating a memory device according to an implementation of the present disclosure is applied. FIG. 12 shows a schematic diagram of bit flipping caused by offsetting read voltage levels in the process of FIG. 11. In FIG. 12, a memory cell in the gray area has a read value of “1”, and a memory cell in the white area has a read value of “0”.

Comparing the process 700′ with the process 700, the difference lies in steps S708′ and S712′, for example, step S708′ offsets RVL1 to the left while offsetting RVL5 to the right, and step S712′ offsets RVL1 to the right while offsetting RVL5 to the left.

Referring to FIG. 12, (A) corresponds to D0 and D00, (B) corresponds to D1 and D00, and (C) corresponds to D2 and D00.

Since the process 700′ performs the offsetting of levels in a manner different from the process 700, the calculation process of its Δ also changes accordingly. For example, in an example implementation, it is determined that the count of bit 1 in D0 is a, the count of bit 1 in D1 is b, the count of bit 1 in D2 is c, the count of bit 1 in (D00 XOR D0) is d, the count of bit 1 in (D00 XOR D1) is e, and the count of bit 1 in (D00 XOR D2) is f. Then it is determined that the number of 1→0 bit flipping caused by offsetting RVL1 to the left is \textcircled{1}=(a−b+d−e)/2, the number of 0→1 bit flipping caused by offsetting RVL1 to the right is \textcircled{1}=(f−d−a+c)/2, the number of 0→1 bit flipping caused by offsetting RVL5 to the left is \textcircled{3}=(c-a-f+d)/2, and the number of 1→0 bit flipping caused by offsetting RVL5 to the right is \textcircled{4}=(a−b+e−d)/2, thereby determining Δ_{RV1}=\textcircled{1}−\textcircled{2}, and Δ_{RV5}=\textcircled{3}−\textcircled{4}. Other example implementations can also be adaptively modified, which are not repeated herein.

From the above, it can be seen that according to the method of the present disclosure, it is possible to quickly find the set of optimal read voltage levels for respective read voltages corresponding to the target page by simultaneously offsetting levels of multiple read voltages corresponding to the target page, and it is possible to process respective read results of the target page by leveraging the read result of the indication page to accurately and simply determine the bit flipping information associated with the respective read voltages corresponding to the target page from at least one of the counts of bit “0” or the counts of bit “1” in the resulting data, respectively. Therefore, the read voltage levels are determined for the respective read voltages corresponding to the target page without relying on the hardware to support data comparison for each individual memory cell, which not only significantly reduces the requirement for the hardware, but also greatly reduces the data cache size.

Additionally, in the processes shown in FIG. 9 and FIG. 11, in addition to leaving the iterative loop from step S718 “No” and step S724 “Yes”, in some implementations, the following conditions for leaving the iterative loop can also be applied: determining whether the read result D0 obtained by reading the LP with the first set of read voltage levels (RVL1₀, RVL5₀) is consistent with the data previously written into the LP. If they are consistent (which means the data stored in the LP can be read successfully with the first set of read voltage levels (RVL1₀, RVL5₀) in this case), the first set of read voltage levels (RVL1₀, RVL5₀) is determined as the set of optimal read voltage levels for the respective read voltages (RV1, RV5) of the LP (S726). For example, this determination step may be between step S704 and step S706, and it proceeds to step S706 in the case of inconsistency (which means the read fails).

The method of operating a memory device taught in the present disclosure can be implemented in various ways. For example, it can be implemented by a memory controller or firmware software, or can be developed into a memory device. For example, the method of operating a memory device taught in the present disclosure may be run when a memory device (such as the memory device 104 in FIG. 1), a memory system (such as the memory system 102 in FIG. 1) containing the memory device, or a system (such as the system 100 in FIG. 1) containing the memory system leaves the factory or is activated, or it can be run every preset period of time (for example, during an patrol operation on a state of the target page). It can also be run in response to a read failure (e.g., the read result is inconsistent with the data previously written) or an error correction command. In some implementations, the method 600 may include performing steps S602 to S610 in response to a failure to read data stored in the first logical page. For example, the failure to read the data stored in the first logical page includes the read data in the first logical page containing an error (for example, an error detected by such as the error correction module 1064 in FIG. 6). In some implementations, the method 600 may include performing steps S602 to S610 during the patrol operation on the state of the first logical page.

The method of operating a memory device taught in the present disclosure can read or re-read the data in the target page after determining or re-determining the optimal read voltage levels. In some implementations, the method 600 may include performing a read operation on the first logical page with the determined (for example, at step S610) set of optimal read voltage levels for the respective read voltages corresponding to the first logical page so as to read the data stored in the first logical page.

According to some aspects of the present disclosure, the present disclosure provides a memory device (such as the memory device 300 in FIG. 3), which includes an array of memory cells (such as the array 301 of memory cells in FIG. 3) and a peripheral circuit (such as the peripheral circuit 302 in FIG. 3) coupled to the array of memory cells. The peripheral circuit may be configured to perform the method of operating a memory device according to any implementation of the present disclosure.

For example, referring to FIG. 5, the peripheral circuit may include the control logic unit 512 and the register 514 coupled to the control logic unit 512. The register 514 may store instructions which, when executed by the control logic unit 512, cause the control logic unit 512 to perform the method of operating a memory device according to any implementation of the present disclosure. In some examples, the control logic unit 512 may send a control signal to the page buffer/sense amplifier 504 so as to read data from the array 301 of memory cells. The control logic unit 512 may control the voltage generator 510 to generate a read voltage to be supplied to the array 301 of memory cells at the desired level (for example, the various read voltage levels described with respect to the method 600).

According to some aspects of the present disclosure, the present disclosure provides a memory system (such as the memory system 102 in FIG. 1), which includes a memory controller (such as the memory controller 106 in FIG. 1) and a memory device (such as the memory device 104 in FIG. 1) coupled to the memory controller. The memory device (such as the memory device 300 in FIG. 3) includes an array of memory cells (such as the array 301 of memory cells in FIG. 3) and a peripheral circuit (such as the peripheral circuit 302 in FIG. 3) coupled to the array of memory cells. The peripheral circuit may be configured to perform the method of operating a memory device according to any implementation of the present disclosure. In some implementations, the peripheral circuit can be configured to perform the following operations.

The operations include performing, with a first set of read voltage levels for respective read voltages corresponding to a first logical page of the array of memory cells, a read operation on the first logical page to obtain a first read result of the first logical page.

The operations further include performing, with a second set of read voltage levels for the respective read voltages corresponding to the first logical page, a read operation on the first logical page to obtain a second read result of the first logical page, wherein the second set of read voltage levels has a first offset relative to the first set of read voltage levels.

The operations further include performing, with a third set of read voltage levels for the respective read voltages corresponding to the first logical page, a read operation on the first logical page to obtain a third read result of the first logical page, wherein the third set of read voltage levels has a second offset relative to the first set of read voltage levels, the second offset being different from the first offset.

The operations further include performing, with a fourth set of read voltage levels for respective read voltages corresponding to a second logical page of the array of memory cells, a read operation on the second logical page to obtain a fourth read result of the second logical page, the second logical page being different from the first logical page.

The operations further include determining a set of optimal read voltage levels for the respective read voltages corresponding to the first logical page based on the first read result, the second read result, the third read result, and the fourth read result.

In some implementations, the peripheral circuit is configured to perform the operations in response to a failure to read data stored in the first logical page. For example, the failure to read the data stored in the first logical page includes the read data in the first logical page containing an error. In some implementations, the peripheral circuit is configured to perform the operations during an patrol operation on a state of the first logical page.

The memory device taught in the present disclosure can read or re-read the data in the target page after the optimal read voltage levels are determined or re-determined. In some implementations, the peripheral circuit is configured to perform, with the set of optimal read voltage levels for the respective read voltages corresponding to the first logical page, a read operation on the first logical page to read the data stored in the first logical page.

In some implementations, the peripheral circuit may be configured to: receive a read command from the memory controller (e.g., from a memory interface (such as the memory I/F 1062 of FIG. 6) of the memory controller via an input/output circuit (such as the input/output circuit 516 of FIG. 5) of the peripheral circuit) to read the data stored in the first logical page with a set of read voltage levels stored in the memory controller for the first logical page; perform the operations in response to determining that the reading the data stored in the first logical page fails; re-read the data stored in the first logical page with the determined set of optimal read voltage levels; and send the data stored in the first logical page to the memory controller. For example, the peripheral circuit may also be configured to send the determined set of optimal read voltage levels for the first logical page to the memory controller. Thus, the memory controller can update the set of read voltage levels stored therein for the first logical page for use when subsequently sending a read command with respect to the first logical page.

In such an implementation, the process of re-determining the optimal read voltage levels by the memory device can be imperceptible to the memory controller. For the memory controller, it sends a read command with respect to the first logical page to the memory device, and then receives the data stored in the first logical page from the memory device.

In some other implementations, the peripheral circuit may be configured to: receive a read command from the memory controller (e.g., from the memory interface (such as the memory I/F 1062 of FIG. 6) of the memory controller via the input/output circuit (such as the input/output circuit 516 of FIG. 5) of the peripheral circuit) to read the data stored in the first logical page with the set of read voltage levels stored in the memory controller for the first logical page; notify the memory controller of a read failure in response to determining that the reading the data stored in the first logical page fails; perform the operations in response to receiving an error correction command from the memory controller (e.g., from the memory interface (such as the memory I/F 1062 of FIG. 6) of the memory controller via the input/output circuit (such as the input/output circuit 516 of FIG. 5) of the peripheral circuit); and send the determined set of optimal read voltage levels for the first logical page to the memory controller. Thus, the memory controller is configured to: receive and store the set of optimal read voltage levels for the first logical page from the peripheral circuit; send a read command to the peripheral circuit (e.g., to the input/output circuit (such as the input/output circuit 516 of FIG. 5) of the peripheral circuit via the memory interface (such as the memory I/F 1062 of FIG. 6) of the memory controller) to read the data stored in the first logical page with the set of optimal read voltage levels stored in the memory controller for the first logical page; and receive the data stored in the first logical page from the peripheral circuit (e.g., from the input/output circuit (such as the input/output circuit 516 of FIG. 5) of the peripheral circuit via the memory interface (such as the memory I/F 1062 of FIG. 6) of the memory controller).

Compared with the aforementioned implementations, in this implementation, the process of re-determining the optimal read voltage levels by the memory device may be completed under the error correction command of the memory controller.

In some other implementations, the process of re-determining the optimal read voltage levels by the memory device may also be automatically completed by the memory device without having to respond to specific instructions of the memory controller.

In some implementations, the determination of the failure to read the data stored in the first logical page may be performed by the memory device (for example, its peripheral circuit), for example, by comparing the data currently read from the first logical page with the data previously programmed (written) to the first logical page.

In some other implementations, the determination of the failure to read the data stored in the first logical page may also be performed by the memory controller (for example, its error correction module). In such an implementation, the aforementioned step “notify the memory controller of a read failure in response to determining that the reading the data stored in the first logical page fails” can be removed. The peripheral circuit is instead configured to send the read data of the first logical page to the memory controller, and perform the process of re-determining the optimal read voltage levels after receiving an error correction command issued by the memory controller based on a determination of a failure to read the data stored in the first logical page.

In some implementations, the memory device may include an input/output circuit coupled to the peripheral circuit and coupled to the memory controller. In some examples, the peripheral circuit is configured to: perform the operations in response to receiving an error correction command from the memory controller via the input/output circuit. In some examples, the peripheral circuit is configured to: perform, with the set of optimal read voltage levels for the respective read voltages corresponding to the first logical page, a read operation on the first logical page to read data stored in the first logical page in response to receiving a read command from the memory controller via the input/output circuit. In some examples, the peripheral circuit is configured to: perform the operations in response to receiving a read command from the memory controller via the input/output circuit, and perform, with the set of optimal read voltage levels for the respective read voltages corresponding to the first logical page, a read operation on the first logical page to read data stored in the first logical page. In some examples, the peripheral circuit is configured to: perform the operations in response to receiving an patrol operation command from the memory controller via the input/output circuit.

According to some aspects of the present disclosure, the present disclosure provides a memory controller (such as the memory controller 106 in FIG. 1 and FIG. 6) for controlling a memory device (such as the memory device 104 in FIG. 1 and FIG. 6). The memory controller includes a memory interface (such as the memory I/F 1062 in FIG. 6) for connecting the memory controller with the memory device. The memory controller includes a processor (such as the processor 1063 in FIG. 6) and a memory (such as the memory 1065 in FIG. 6) coupled to the processor and storing instructions. The instructions, when executed by the processor, cause the processor to perform the method of operating a memory device according to any implementation of the present disclosure. In some implementations, the instructions, when executed by the processor, cause the processor to perform the following operations: instructing the memory interface to send a first read command to the memory device to perform a read operation on a first logical page of the memory device with a first set of read voltage levels for respective read voltages corresponding to the first logical page, and receive a first read result of the first logical page from the memory device; instructing the memory interface to send a second read command to the memory device to perform a read operation on the first logical page with a second set of read voltage levels for the respective read voltages corresponding to the first logical page, and receive a second read result of the first logical page from the memory device, wherein the second set of read voltage levels has a first offset relative to the first set of read voltage levels; instructing the memory interface to send a third read command to the memory device to perform a read operation on the first logical page with a third set of read voltage levels for the respective read voltages corresponding to the first logical page, and receive a third read result of the first logical page from the memory device, wherein the third set of read voltage levels has a second offset relative to the first set of read voltage levels, the second offset being different from the first offset; instructing the memory interface to send a fourth read command to the memory device to perform a read operation on a second logical page of the memory device with a fourth set of read voltage levels for respective read voltages corresponding to the second logical page, and receive a fourth read result of the second logical page from the memory device, the second logical page being different from the first logical page; and determining a set of optimal read voltage levels for the respective read voltages corresponding to the first logical page based on the first read result, the second read result, the third read result, and the fourth read result.

In some implementations, the instructions, when executed by the processor, cause the processor to: perform the operations in response to a failure to read data stored in the first logical page. For example, the failure to read the data stored in the first logical page may include the read data in the first logical page containing an error. In some implementations, the instructions, when executed by the processor, cause the processor to: perform the operations during an patrol operation on a state of the first logical page.

In some implementations, the instructions, when executed by the processor, cause the processor to: instruct the memory to adjust read voltage levels stored in the memory for the respective read voltages corresponding to the first logical page to the set of optimal read voltage levels.

In some implementations, the instructions, when executed by the processor, cause the processor to: instruct the memory interface to send a fifth read command to the memory device to perform a read operation on the first logical page with the set of optimal read voltage levels for the respective read voltages corresponding to the first logical page, and receive data stored in the first logical page from the memory device.

In some implementations, the processor may: instruct the memory interface to send a read command to the memory device to read data stored in the first logical page with a set of read voltage levels stored in the memory for the first logical page, and receive the data stored in the first logical page from the memory device; perform the operations in response to determining a failure to read the data stored in the first logical page (for example, detecting an error via an error correction module (such as the error correction module 1064 in FIG. 6)) to update the set of read voltage levels stored by the memory for the first logical page to the determined set of optimal read voltage levels for the first logical page (for example, the processor can send to the memory an instruction to adjust the read voltage levels to the determined optimal read voltage levels); instruct the memory interface to re-send a read command to the memory device to read the data stored in the first logical page with the set of optimal read voltage levels stored in the memory for the first logical page, and receive the data stored in the first logical page from the memory device.

In such an implementation, the process of re-determining the optimal read voltage levels by the memory controller can be imperceptible to the memory device. For the memory device, it receives a read command with respect to the first logical page from the memory controller (for example, its memory interface), and then sends the data stored in the first logical page to the memory controller (for example, its memory interface).

According to some aspects of the present disclosure, the present disclosure provides a memory system (such as the memory system 102 in FIG. 1 and FIG. 6), which includes a memory device (such as the memory device 104 in FIG. 1 and FIG. 6) and a memory controller (such as the memory controller 106 in FIG. 1 and FIG. 6) coupled to the memory device. The memory controller may be configured to perform the method of operating a memory device according to any implementation of the present disclosure. In some implementations, the memory controller can be configured to perform the following operations: sending a first read command to the memory device to perform a read operation on a first logical page of the memory device with a first set of read voltage levels for respective read voltages corresponding to the first logical page, and receiving a first read result of the first logical page from the memory device; sending a second read command to the memory device to perform a read operation on the first logical page with a second set of read voltage levels for the respective read voltages corresponding to the first logical page, and receiving a second read result of the first logical page from the memory device, wherein the second set of read voltage levels has a first offset relative to the first set of read voltage levels; sending a third read command to the memory device to perform a read operation on the first logical page with a third set of read voltage levels for the respective read voltages corresponding to the first logical page, and receiving a third read result of the first logical page from the memory device, wherein the third set of read voltage levels has a second offset relative to the first set of read voltage levels, the second offset being different from the first offset; sending a fourth read command to the memory device to perform a read operation on a second logical page of the memory device with a fourth set of read voltage levels for respective read voltages corresponding to the second logical page, and receiving a fourth read result of the second logical page from the memory device, the second logical page being different from the first logical page; and determining a set of optimal read voltage levels for the respective read voltages corresponding to the first logical page based on the first read result, the second read result, the third read result, and the fourth read result.

In some implementations, the memory controller is configured to perform the operations in response to a failure to read data stored in the first logical page. For example, the failure to read the data stored in the first logical page may include the read data in the first logical page containing an error. In some implementations, the memory controller is configured to perform the operations during an patrol operation on a state of the first logical page.

In some implementations, the memory controller is configured to adjust read voltage levels stored by the memory controller for the respective read voltages corresponding to the first logical page to the set of optimal read voltage levels.

In some implementations, the memory controller is configured to: send a fifth read command to the memory device to perform a read operation on the first logical page with the set of optimal read voltage levels for the respective read voltages corresponding to the first logical page, and receive data stored in the first logical page from the memory device.

In some implementations, the memory controller is configured to: send a read command to the memory device (for example, via a memory interface (such as the memory I/F 1062 in the FIG. 6)) to read data stored in the first logical page with a set of read voltage levels stored in the memory controller for the first logical page, and receive the data stored in the first logical page from the memory device; perform the operations in response to determining a failure to read the data stored in the first logical page (for example, detecting an error via an error correction module (such as the error correction module 1064 in FIG. 6)) to update the set of read voltage levels stored by the memory controller for the first logical page to the determined set of optimal read voltage levels for the first logical page (for example, an instruction to adjust the read voltage levels to the determined optimal read voltage levels can be sent to a memory (such as the memory 1065 in FIG. 6) via a processor (such as the processor 1063 in FIG. 6)); re-send a read command to the memory device (for example, via the memory interface (such as the memory I/F 1062 in the FIG. 6)) to read the data stored in the first logical page with the set of optimal read voltage levels stored in the memory controller for the first logical page, and receive the data stored in the first logical page from the memory device.

In such an implementation, the process of re-determining the optimal read voltage levels by the memory controller can be imperceptible to the memory device. For the memory device, it receives a read command with respect to the first logical page from the memory controller, and then sends the read data to the memory controller.

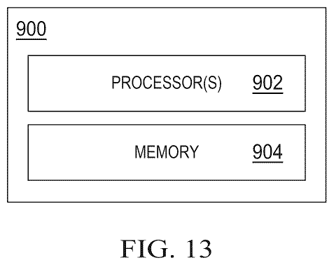

The present disclosure also provides an electronic device, which may include one or more processors and a memory storing computer-executable instructions which, when executed by the one or more processors, cause the one or more processors to perform the method of operating a memory device according to any aforementioned implementation of the present disclosure. As shown in FIG. 13, an electronic device 900 includes a processor(s) 902 and a memory 904 storing computer-executable instructions which, when executed by the processor(s) 902, cause the processor(s) 902 to perform the method of operating a memory device according to any aforementioned implementation of the present disclosure. The processor(s) 902 may, for example, be a central processing unit (CPU) of the electronic device 900. The processor(s) 902 may be any type of general-purpose processor, or may be a processor specially designed to operate a memory device, such as an application specific integrated circuit (“ASIC”). The memory 904 may include various computer-readable media that can be accessed by the processor(s) 902. In various implementations, the memory 904 described herein may include volatile and non-volatile media as well as removable and non-removable media. For example, the memory 904 may include any combination of the following: a random access memory (“RAM”), a dynamic RAM (“DRAM”), a static RAM (“SRAM”), a read-only memory (“ROM”), a flash memory, a cache memory, and/or any other type of non-transitory computer-readable medium. The memory 904 may store instructions which, when executed by the processor 902, cause the processor 902 to perform the method of operating a memory device according to any aforementioned implementation of the present disclosure.

The present disclosure further provides a non-transitory storage medium storing computer-executable instructions thereon which, when executed by one or more processors, cause the one or more processors to perform the method of operating a memory device according to any aforementioned implementations of the present disclosure.

The present disclosure further provides a computer program product that may include instructions which, when executed by a processor, may implement the method of operating a memory device according to any aforementioned implementation of the present disclosure. The instructions may be any instruction set to be executed directly by one or more processors, such as machine codes, or any instruction set to be executed indirectly, such as scripts. The instructions can be stored in a format of object codes for direct processing by one or more processors, or stored in any other computer language, including scripts or collections of independent source code modules that are interpreted on demand or compiled in advance.

The foregoing describes one or more implementations of the present disclosure. Other implementations are within the scope of the attached claims. In some cases, actions or steps recited in the claims can be performed in an order different from that in the implementations and the desired results can still be achieved. In addition, the processes depicted in the drawings do not necessarily require the shown particular order or consecutive order for achieving the desired results. In certain implementations, multitasking and parallel processing are also possible or may be advantageous.

The systems, apparatuses, modules, or units set forth in the above implementations may be specifically implemented by a computer chip or entity, or by a product with some function. A typical implementation device is a server system. Certainly, the present disclosure does not exclude that with the development of computer technology in the future, computers that realize the functions of the above-mentioned implementations may, for example, be personal computers, laptop computers, on-board human-machine interaction devices, cellular phones, camera phones, smart phones, personal digital assistants, media players, navigation devices, e-mail devices, game consoles, tablet computers, wearable devices, or combinations of any of these devices.

Although one or more implementations of the present disclosure provide method operating steps as described in the implementations or flowcharts, they may include more or fewer operating steps based on conventional or non-creative means. The order of steps listed in the implementations is merely one way among the numerous step performing orders, and does not represent the only performing order. When performed in actual apparatuses or end products, it is possible to perform sequentially or in parallel (for example, in an environment with a parallel processor or multi-threaded processing, and even in a distributed data processing environment) according to the method shown in the implementations or drawings.

The terms “comprise”, “include”, or any other variant thereof are intended to encompass non-exclusive inclusion, so that a process, method, product, or device that includes a series of elements not only includes those elements, but also includes other elements that are not expressly listed, or further includes elements inherent to such process, method, product, or device. Without more restrictions, it does not exclude that there are other identical or equivalent elements in the process, method, product, or device that includes the elements. For example, if words such as “first” and “second”are used to represent names, they do not represent any particular order.

For the convenience of description, the above apparatus, when described, is divided into various modules according to functions that are described separately. Certainly, when implementing one or more implementations of the present disclosure, the functions of the modules can be implemented in the same one or more software and/or hardware. The modules that achieve the same function can also be implemented by a combination of multiple sub-modules or sub-units, and so on. The apparatus implementations described above are only schematic. For example, the division of the units is merely a logical functional division. In actual implementation, there may be other division ways. For example, multiple units or components can be combined or integrated into another system, or some features can be omitted or not performed. Additionally, the coupling or direct coupling or communication connection between each other as shown or discussed may be indirect coupling or communication connection through some interfaces, apparatuses or units, and may be in the form of electrical, mechanical, or other types.

The present disclosure is described with reference to flowcharts and/or block diagrams of the methods, apparatuses (systems), and computer program products according to the implementations of the present disclosure. It should be understood that each process and/or block in the flowcharts and/or block diagrams, as well as the combinations of the processes and/or blocks in the flowcharts and/or block diagrams, can be implemented by computer program instructions. These computer program instructions can be provided to a general-purpose computer, a special-purpose computer, an embedded processor, or a processor of other programmable data processing device to generate a machine, so that the instructions executed by the computer or the processor of the other programmable data processing devices generate an apparatus for implementing the functions specified in one or more processes of the flowcharts and/or one or more blocks of the block diagrams.

These computer program instructions can also be stored in a computer-readable memory that can guide a computer or other programmable data processing devices to work in a particular manner, so that the instructions stored in the computer-readable memory generate a manufactured product including an instruction apparatus, which implements the functions specified in one or more processes of the flowcharts and/or one or more blocks of the block diagrams. These computer program instructions can also be loaded onto a computer or other programmable data processing devices, so that a series of operating steps are performed on the computer or other programmable devices to generate a computer-implemented processing. Therefore, the instructions executed on the computer or other programmable devices provide steps for implementing the functions specified in one or more processes of the flowcharts and/or one or more blocks of the block diagrams.

Those skilled in the art should understand that one or more implementations of the present disclosure may take the form of a complete hardware implementation, a complete software implementation, or an implementation combining software and hardware aspects. Moreover, one or more implementations of the present disclosure may take the form of a computer program product implemented on one or more computer-available storage media (including but not limited to disk memory, CD-ROM, optical memory, etc.) that contain computer-available program codes therein.

One or more implementations of the present disclosure may be described in the general context of computer-executable instructions executed by a computer, for example, program modules. Generally, the program modules include routines, programs, objects, assemblies, data structures, etc. that perform particular tasks or implement particular abstract data types. One or more implementations of the present disclosure can also be practiced in a distributed computing environment where a task is performed by a remote processing device connected through a communication network. In the distributed computing environment, the program modules can reside in local and remote computer storage media including storage devices.

The same or similar parts among the various implementations of the present disclosure can refer to each other, and each implementation focuses on the differences from other implementations. In particular, for the apparatus implementations, since they are substantially similar to the method implementations, their description are relatively simple, and relevant parts can refer to portions of the description of the method implementations. In the description of the present disclosure, descriptions with reference to the terms “one implementation”, “some implementations”, “an example”, “a specific example”, “some examples”, or the like mean that specific features, structures, materials, or characteristics described in conjunction with the implementation or example are included in at least one implementation or example of the present disclosure. In the present disclosure, schematic descriptions of the foregoing terms do not necessarily refer to the same implementation or example. In addition, the described specific features, structures, materials, or characteristics may be combined in proper manners in any one or more implementations or examples. In addition, without contradicting each other, those skilled in the art can combine and assemble different implementations or examples as well as features of different implementations or examples described in the present disclosure.

In addition, when used in the present disclosure, the words “herein”, “foregoing”, “following”, “hereinafter”, “hereinabove” and words of similar meanings shall refer to the entirety of the present disclosure but not any particular part of the present disclosure. Moreover, unless otherwise stated expressly or interpreted in other manners in the used context, conditional language for example, “may”, “can”, “for example”, “such as” and the like used herein are usually intended to express that some implementations include some features, elements, and/or states but other implementations do not. Therefore, this conditional language is usually not intended to imply that one or more implementations require the features, elements, and/or states in any manner, or whether include these features, elements, and/or states, or these features, elements, and/or states are performed in any particular implementation.

The above descriptions are only implementations of one or more implementations of the present disclosure, and are not used to limit one or more implementations of the present disclosure. For those skilled in the art, one or more implementations of the present disclosure may have various changes and variations. Any modification, equivalent replacement, improvement, and the like made within the spirit and principle of the present disclosure shall be included within the scope of the claims.

What is claimed is:

1. A method of operating a memory device, comprising:
performing, with a first set of read voltage levels for respective read voltages corresponding to a first logical page of the memory device, a read operation on the first logical page to obtain a first read result of the first logical page;
performing, with a second set of read voltage levels for the respective read voltages corresponding to the first logical page, a read operation on the first logical page to obtain a second read result of the first logical page, wherein the second set of read voltage levels has a first offset relative to the first set of read voltage levels;
performing, with a third set of read voltage levels for the respective read voltages corresponding to the first logical page, a read operation on the first logical page to obtain a third read result of the first logical page, wherein the third set of read voltage levels has a second offset relative to the first set of read voltage levels, the second offset being different from the first offset;
performing, with a fourth set of read voltage levels for respective read voltages corresponding to a second logical page of the memory device, a read operation on the second logical page to obtain a fourth read result of the second logical page, the second logical page being different from the first logical page; and
determining a set of optimal read voltage levels for the respective read voltages corresponding to the first logical page based on the first read result, the second read result, the third read result, and the fourth read result.

2. The method of claim 1, wherein the first logical page corresponds to a first read voltage and a second read voltage,
the first offset is configured such that an offset of a read voltage level from the second set of read voltage levels for the first read voltage relative to a read voltage level from the first set of read voltage levels for the first read voltage has the same offset direction as an offset of a read voltage level from the second set of read voltage levels for the second read voltage relative to a read voltage level from the first set of read voltage levels for the second read voltage, and
the second offset is configured such that an offset of a read voltage level from the third set of read voltage levels for the first read voltage relative to the read voltage level from the first set of read voltage levels for the first read voltage has the same offset direction as an offset of a read voltage level from the third set of read voltage levels for the second read voltage relative to the read voltage level from the first set of read voltage levels for the second read voltage.

3. The method of claim 1, wherein the first logical page corresponds to a first read voltage and a second read voltage,
the first offset is configured such that an offset of a read voltage level from the second set of read voltage levels for the first read voltage relative to a read voltage level from the first set of read voltage levels for the first read voltage has an opposite offset direction from an offset of a read voltage level from the second set of read voltage levels for the second read voltage relative to a read voltage level from the first set of read voltage levels for the second read voltage, and
the second offset is configured such that an offset of a read voltage level from the third set of read voltage levels for the first read voltage relative to the read voltage level from the first set of read voltage levels for the first read voltage has an opposite offset direction from an offset of a read voltage level from the third set of read voltage levels for the second read voltage relative to the read voltage level from the first set of read voltage levels for the second read voltage.

4. The method of claim 1, wherein the first logical page corresponds to three or more read voltages, the three or more read voltages comprising a first read voltage and a second read voltage, and wherein,
the first offset is configured such that:
an offset of a read voltage level from the second set of read voltage levels for the first read voltage relative to a read voltage level from the first set of read voltage levels for the first read voltage has a non-zero offset magnitude,
an offset of a read voltage level from the second set of read voltage levels for the second read voltage relative to a read voltage level from the first set of read voltage levels for the second read voltage has a non-zero offset magnitude, and
an offset of a read voltage level from the second set of read voltage levels for each read voltage from the three or more read voltages except for the first read voltage and the second read voltage relative to a read voltage level from the first set of read voltage levels for the each read voltage has an offset magnitude of zero, and
the second offset is configured such that:
an offset of a read voltage level from the third set of read voltage levels for the first read voltage relative to the read voltage level from the first set of read voltage levels for the first read voltage has a non-zero offset magnitude,
an offset of a read voltage level from the third set of read voltage levels for the second read voltage relative to the read voltage level from the first set of read voltage levels for the second read voltage has a non-zero offset magnitude, and
an offset of a read voltage level from the third set of read voltage levels for each read voltage from the three or more read voltages except for the first read voltage and the second read voltage relative to the read voltage level from the first set of read voltage levels for the each read voltage has an offset magnitude of zero.

5. The method of claim 1, comprising:
determining the first set of read voltage levels as the set of optimal read voltage levels in response to determining not to offset the first set of read voltage levels to obtain the set of optimal read voltage levels based on the first read result, the second read result, the third read result, and the fourth read result.

6. The method of claim 1, comprising:
determining an offset direction and an offset value for offsetting the first set of read voltage levels based on the first read result, the second read result, the third read result, and the fourth read result, in response to determining to offset the first set of read voltage levels to obtain the set of optimal read voltage levels based on the first read result, the second read result, the third read result, and the fourth read result; and
determining a first offset magnitude to be applied to the first offset and a second offset magnitude to be applied to the second offset based on the determined offset direction.

7. The method of claim 6, comprising in response to determining that the first offset magnitude and the second offset magnitude exceed a preset offset magnitude threshold:
performing, with the first set of read voltage levels updated based on the offset value for the respective read voltages corresponding to the first logical page, a read operation on the first logical page to re-obtain the first read result of the first logical page;
performing, with the second set of read voltage levels updated based on the offset value and the first offset magnitude for the respective read voltages corresponding to the first logical page, a read operation on the first logical page to re-obtain the second read result of the first logical page;
performing, with the third set of read voltage levels updated based on the offset value and the second offset magnitude for the respective read voltages corresponding to the first logical page, a read operation on the first logical page to re-obtain the third read result of the first logical page; and
determining the set of optimal read voltage levels for the respective read voltages corresponding to the first logical page based on the re-obtained first read result, the re-obtained second read result, the re-obtained third read result, and the fourth read result.

8. The method of claim 1, wherein determining the set of optimal read voltage levels for the respective read voltages corresponding to the first logical page based on the first read result, the second read result, the third read result, and the fourth read result comprises:
determining the set of optimal read voltage levels for the respective read voltages corresponding to the first logical page based on first data generated from the first read result and the fourth read result, second data generated from the second result and the fourth read result, and third data generated from the third read result and the fourth read result.

9. The method of claim 8, wherein the first data, the second data, and the third data are generated by performing Boolean operations on the first read result, the second read result, and the third read result with the fourth read result, respectively.

10. The method of claim 9, comprising:
determining at least one of a count of bit 1 or a count of bit 0 in each of the first to third data; and
determining a difference between a number of bit flipping caused by the first offset and a number of bit flipping caused by the second offset based on the at least one of the count of bit 1 or the count of bit 0 for each read voltage corresponding to the first logical page,
wherein determining the set of optimal read voltage levels for the respective read voltages corresponding to the first logical page based on the first read result, the second read result, the third read result, and the fourth read result comprises:
determining the set of optimal read voltage levels for the respective read voltages corresponding to the first logical page based on the difference.

11. The method of claim 10, comprising:
determining the first set of read voltage levels as the set of optimal read voltage levels in response to determining that an absolute value of the difference does not exceed a preset difference threshold; and
determining an offset direction and an offset value for offsetting the first set of read voltage levels based on a sign of the difference in response to determining that an absolute value of the difference exceeds a preset difference threshold.

12. The method of claim 1, wherein the first logical page and the second logical page satisfy at least one of the following:
the first logical page and the second logical page corresponding to the same physical page of the memory device; or
a first physical page corresponding to the first logical page of the memory device and a second physical page corresponding to the second logical page of the memory device being coupled to the same word line of the memory device; or
a first word line coupled to the first physical page corresponding to the first logical page of the memory device and a second word line coupled to the second physical page corresponding to the second logical page of the memory device being included in the same set of word lines of the memory device.

13. The method of claim 1, wherein the respective read voltages corresponding to the first logical page include a first read voltage and a second read voltage, the respective read voltages corresponding to the second logical page include a third read voltage, and the third read voltage is between the first read voltage and the second read voltage.

14. The method of claim 13, wherein the respective read voltages corresponding to the second logical page include only one read voltage between the first read voltage and the second read voltage.

15. A memory system, comprising:
a memory controller; and
a memory device coupled to the memory controller and comprising an array of memory cells and a peripheral circuit, the peripheral circuit being coupled to the array of memory cells and configured to perform the following operations:
performing, with a first set of read voltage levels for respective read voltages corresponding to a first logical page of the array of memory cells, a read operation on the first logical page to obtain a first read result of the first logical page;
performing, with a second set of read voltage levels for the respective read voltages corresponding to the first logical page, a read operation on the first logical page to obtain a second read result of the first logical page, wherein the second set of read voltage levels has a first offset relative to the first set of read voltage levels;
performing, with a third set of read voltage levels for the respective read voltages corresponding to the first logical page, a read operation on the first logical page to obtain a third read result of the first logical page, wherein the third set of read voltage levels has a second offset relative to the first set of read voltage levels, the second offset being different from the first offset;
performing, with a fourth set of read voltage levels for respective read voltages corresponding to a second logical page of the array of memory cells, a read operation on the second logical page to obtain a fourth read result of the second logical page, the second logical page being different from the first logical page; and
determining a set of optimal read voltage levels for the respective read voltages corresponding to the first logical page based on the first read result, the second read result, the third read result, and the fourth read result.

16. The memory system of claim 15, wherein the memory device comprises an input/output circuit coupled to the peripheral circuit and to the memory controller, and the peripheral circuit is configured to:
perform the operations in response to receiving an error correction command from the memory controller via the input/output circuit.

17. The memory system of claim 15, wherein the memory device comprises an input/output circuit coupled to the peripheral circuit and to the memory controller, and the peripheral circuit is configured to:
perform, with the set of optimal read voltage levels for the respective read voltages corresponding to the first logical page, a read operation on the first logical page to read data stored in the first logical page in response to receiving a read command from the memory controller via the input/output circuit.

18. The memory system of claim 15, wherein the memory device comprises an input/output circuit coupled to the peripheral circuit and to the memory controller, and the peripheral circuit is configured to:
perform the operations in response to receiving a read command from the memory controller via the input/output circuit; and
perform, with the set of optimal read voltage levels for the respective read voltages corresponding to the first logical page, a read operation on the first logical page to read data stored in the first logical page.

19. The memory system of claim 15, wherein the memory device comprises an input/output circuit coupled to the peripheral circuit and to the memory controller, and the peripheral circuit is configured to:
perform the operations in response to receiving an patrol operation command from the memory controller via the input/output circuit.

20. A memory controller configured to control a memory device, the memory controller comprising:
a memory interface for connecting the memory controller with the memory device;
a processor; and
a memory coupled to the processor and storing instructions which, when executed by the processor, cause the processor to perform the following operations:
instructing the memory interface to send a first read command to the memory device to perform a read operation on a first logical page of the memory device with a first set of read voltage levels for respective read voltages corresponding to the first logical page, and receive a first read result of the first logical page from the memory device;
instructing the memory interface to send a second read command to the memory device to perform a read operation on the first logical page with a second set of read voltage levels for the respective read voltages corresponding to the first logical page, and receive a second read result of the first logical page from the memory device, wherein the second set of read voltage levels has a first offset relative to the first set of read voltage levels;
instructing the memory interface to send a third read command to the memory device to perform a read operation on the first logical page with a third set of read voltage levels for the respective read voltages corresponding to the first logical page, and receive a third read result of the first logical page from the memory device, wherein the third set of read voltage levels has a second offset relative to the first set of read voltage levels, the second offset being different from the first offset;
instructing the memory interface to send a fourth read command to the memory device to perform a read operation on a second logical page of the memory device with a fourth set of read voltage levels for respective read voltages corresponding to the second logical page, and receive a fourth read result of the second logical page from the memory device, the second logical page being different from the first logical page; and
determining a set of optimal read voltage levels for the respective read voltages corresponding to the first logical page based on the first read result, the second read result, the third read result, and the fourth read result.
